(19) United States
(12) Patent Application Publication
(10) Pub. No.: US 2026/0092352 A1
(43) Pub. Date: Apr. 2, 2026

(54) DEPOSITION MASK AND METHOD OF MANUFACTURING THE SAME

(71) Applicant: Samsung Display Co., LTD., Yongin-si (KR)

(72) Inventors: Jeong Kuk KIM, Yongin-si (KR); Dong Uk KANG, Yongin-si (KR); Young Jin SONG, Yongin-si (KR); Byeong Hoon CHO, Yongin-si (KR)

(21) Appl. No.: 19/215,905

(22) Filed: May 22, 2025

(30) Foreign Application Priority Data
Oct. 2, 2024 (KR) 10-2024-0133637

(51) Int. Cl. C23C 14/04; C23C 14/24; H10K 71/16

(52) U.S. Cl. CPC C23C 14/042; H10K 71/166; C23C 14/24

(57) ABSTRACT

A deposition mask includes a mask substrate disposed to surround a mask opening; a main coating film disposed on the mask substrate; and a mask pattern disposed to overlap the mask opening and spaced apart from the main coating film with a pixel opening interposed therebetween. The mask substrate includes a first surface facing the main coating film; a second surface opposing the first surface; a side surface facing the mask opening and extending to the first surface and the second surface, and a first inclination angle defined by the first surface and the side surface of the mask substrate is 53° or more and 55° or less.

This application claims priority to Korean Patent Application No. 10-2024-0133637, filed on Oct. 2, 2024, and all the benefits accruing therefrom under 35 U.S.C. § 119, the content of which in its entirety is herein incorporated by reference.

### BACKGROUND

### 1. Field

The disclosure relates to a deposition mask and a method of manufacturing the same.

### 2. Description of the Related Art

As the information society develops, the demand for display devices for displaying images has increased and diversified. The display devices may be display devices such as liquid crystal displays (“LCDs”), field emission displays (“FEDs”), or light-emitting displays (“LEDs”). The light-emitting display may include an organic light-emitting display including organic light-emitting diode elements as light-emitting elements, an inorganic light-emitting display including inorganic light-emitting diode elements as light-emitting elements, or the like.

Recently, a need for a display device that provides a high-resolution image such as an image having a resolution of 3,000 pixels per inch (“PPI”) or higher has increased. To this end, an organic light-emitting diode on silicon (“OLEDoS”), which is a relatively small organic light-emitting display device having a relatively high resolution, has been used. The OLEDoS is a device that displays an image by disposing organic light-emitting diodes (“OLEDs”) on a semiconductor wafer substrate including complementary metal oxide semiconductors (“CMOSs”).

In order to manufacture a self-light-emitting display device such as an organic light-emitting display device, a deposition method of bringing a thin film mask into close contact with a substrate and depositing an organic material at a desired position is mainly used as a technology for depositing an organic material for each pixel. When an organic material is deposited on an organic light-emitting display device having a great area, a fine metal mask (“FMM”), which is a thin film metal mask, has been widely used. However, such a metal mask is not suitable for high-resolution patterning.

Therefore, in order to manufacture a precise thin film mask having a relatively high resolution, a fine silicon mask (“FSM”) manufactured using a semiconductor substrate such as a wafer has emerged.

### SUMMARY

Features of the disclosure provide a deposition mask for manufacturing a high-resolution display device, and a method of manufacturing the same.

Features of the disclosure also provide a deposition mask in which efficiency of a deposition process is improved, and a method of manufacturing the same.

Features of the disclosure also provide a deposition mask in which a coating film peeling defect is solved, and a method of manufacturing the same.

However, features of the disclosure are not restricted to those set forth herein. The above and other features of the disclosure will become more apparent to one of ordinary skill in the art to which the disclosure pertains by referencing the detailed description of the disclosure given below.

In an embodiment of the disclosure, a deposition mask includes a mask substrate disposed to surround a mask opening; a main coating film disposed on the mask substrate; and a mask pattern disposed to overlap the mask opening and spaced apart from the main coating film with a pixel opening interposed therebetween. The mask substrate includes a first surface facing the main coating film; a second surface opposing the first surface; a side surface facing the mask opening and extending to the first surface and the second surface, and a first inclination angle defined by the first surface and the side surface of the mask substrate is 53° or more and 55° or less.

In an embodiment, a second inclination angle defined by the second surface and the side surface of the mask substrate may be an obtuse angle.

In an embodiment, the second inclination angle may be 125° or more and 127° or less.

In an embodiment, the mask substrate may include silicon, and the mask substrate has a circular shape in a plan view.

In an embodiment, a thickness of the mask substrate may be 700 micrometers (μm) or more and 800 μm or less.

In an embodiment, a width of the mask opening in a direction parallel to the mask substrate may become smaller toward the mask pattern in a direction perpendicular to the mask substrate.

In an embodiment, the main coating film may include an upper main coating film disposed on the first surface of the mask substrate; and a lower main coating film disposed on the second surface of the mask substrate.

In an embodiment, a side surface of the lower main coating film facing the mask opening may be disposed on the same line as the side surface of the mask substrate.

In an embodiment, a side surface of the upper main coating film facing the mask opening may be depressed more than the side surface of the mask substrate in a direction opposite to a direction toward the mask opening.

In an embodiment, a side surface of the upper main coating film facing the mask opening may protrude more than the side surface of the mask substrate in a direction toward the mask opening.

In an embodiment, the mask pattern may be disposed on the same line as the main coating film, and the mask pattern and the main coating film include the same material as each other.

In an embodiment, the deposition mask may further include an auxiliary coating film disposed between the mask substrate and the main coating film, and the auxiliary coating film and the main coating film may include different inorganic materials.

In an embodiment, the main coating film and the auxiliary coating film may be disposed to surround the mask opening, the mask pattern and the main coating film include silicon nitride, and the auxiliary coating film includes silicon oxide.

In an embodiment, the pixel opening and the mask opening may be in communication with each other.

In an embodiment of the disclosure, a method of manufacturing a deposition mask, includes forming an auxiliary coating film and a main coating film on a mask substrate and removing a portion of an upper main coating film to define a pixel opening; removing portions of a lower main coating film and a lower auxiliary coating film removing a portion of the mask substrate to define a mask opening; and removing a portion of an upper auxiliary coating film to allow the pixel opening and the mask opening to be in communication with each other, and in the removing the portion of the mask substrate, the mask substrate is removed by a wet etching process.

In an embodiment, in the removing the portion of the mask substrate, the wet etching process may be performed toward a rear surface direction of the mask substrate, and a first inclination angle defined by the mask substrate and the upper auxiliary coating film is an acute angle.

In an embodiment, the first inclination angle may be 53° or more and 55° or less.

In an embodiment, a thickness of the mask substrate may be 700 μm or more and 800 μm or less, and in the removing the portion of the mask substrate, the mask substrate overlapping the mask opening is completely removed.

In an embodiment, in the removing the portion of the upper auxiliary coating film, the upper auxiliary coating film may be removed through a wet etching process performed in a rear surface direction of the mask substrate.

In an embodiment of the disclosure, an electronic device including: a display device formed using a deposition mask; the deposition mask including: a mask substrate disposed to surround a mask opening; a main coating film disposed on the mask substrate; and a mask pattern disposed to overlap the mask opening and spaced apart from the main coating film with a pixel opening interposed therebetween. The mask substrate includes a first surface facing the main coating film; a second surface opposing the first surface; a side surface facing the mask opening and extending to the first surface and the second surface, and a first inclination angle defined by the first surface and the side surface of the mask substrate is 53° or more and 55° or less.

Detailed contents of other embodiments are described in a detailed description and are illustrated in the drawings.

With an embodiment of a deposition mask and a method of manufacturing the same according to the disclosure, a high-resolution display device may be manufactured.

With an embodiment of the deposition mask and the method of manufacturing the same according to the disclosure, efficiency of a deposition process may be improved.

With an embodiment of the deposition mask and the method of manufacturing the same according to the disclosure, a coating film peeling defect may be solved.

The effects of the disclosure are not limited to the aforementioned effects, and various other effects are included in the specification.

### BRIEF DESCRIPTION OF THE DRAWINGS

The above and other advantages and features of the disclosure will become more apparent by describing in detail embodiments thereof with reference to the attached drawings, in which:

FIG. 1 is an exploded perspective view illustrating an embodiment of a display device;

FIG. 2 is a block diagram illustrating an embodiment of the display device;

FIG. 3 is an equivalent circuit diagram of an embodiment of a first sub-pixel;

FIG. 4 is a plan view illustrating an embodiment of a display panel;

FIGS. 5 and 6 are plan views illustrating arrangements of a plurality of pixels in a display area of FIG. 4;

FIG. 7 is a cross-sectional view illustrating an embodiment of the display panel taken along X1-X1′ of FIG. 5;

FIG. 8 is an exploded perspective view illustrating an embodiment of a head disposed (e.g., mounted) display device;

FIG. 9 is a perspective view illustrating an embodiment of an augmented reality content providing device;

FIG. 10 is an exploded perspective view of the augmented reality content providing device of FIG. 9 viewed in a rear surface direction;

FIG. 11 is an exploded perspective view of the augmented reality content providing device of FIG. 10 viewed in a front surface direction;

FIG. 12 is a plan view illustrating an embodiment of a mother semiconductor substrate including a display cell;

FIG. 13 is a plan view illustrating an embodiment of a deposition mask including a mask cell;

FIG. 14 is a schematic view for describing an embodiment of a deposition device of manufacturing a display panel using the deposition mask;

FIG. 15 is a cross-sectional view taken along line X2-X2′ of an embodiment of FIG. 13;

FIG. 16 is a cross-sectional view taken along line X2-X2′ of another embodiment of FIG. 13;

FIG. 17 is a cross-sectional view taken along line X2-X2′ of another embodiment of FIG. 13;

FIG. 18 is a flowchart illustrating an embodiment of a method of manufacturing the deposition mask;

FIGS. 19 to 21 are cross-sectional views illustrating S100 of FIG. 18;

FIGS. 22 and 23 are cross-sectional views illustrating S200 of FIG. 18;

FIGS. 24 to 26 are cross-sectional views illustrating S300 of FIG. 18; and

FIGS. 27 and 28 are cross-sectional views illustrating S400 of FIG. 18.

FIG. 29 is a block diagram of an electronic device according to one embodiment of the present disclosure.

FIG. 30 is a schematic diagram of an electronic device according to various embodiments of the present disclosure.

### DETAILED DESCRIPTION

The disclosure now will be described more fully hereinafter with reference to the accompanying drawings, in which various embodiments are shown. This disclosure may, however, be embodied in many different forms, and should not be construed as limited to the embodiments set forth herein. Rather, these embodiments are provided so that this disclosure will be thorough and complete, and will fully convey the scope of the disclosure to those skilled in the art. Like reference numerals refer to like elements throughout.

It will be understood that when an element is referred to as being “on” another element, it may be directly on the other element or intervening elements may be therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the drawing figures. It will be understood that relative terms are intended to encompass different orientations of the device in addition to the orientation depicted in the drawing figures. In an embodiment, when the device in one of the drawing figures is turned over, elements described as being on the “lower” side of other elements would then be oriented on “upper” sides of the other elements. The term “lower,” may therefore, encompasses both an orientation of “lower” and “upper,” depending on the particular orientation of the figure. Similarly, when the device in one of the drawing figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” may mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the drawing figures are schematic in nature and their shapes are not intended to illustrate the precise shape of a region and are not intended to limit the scope of the claims.

Hereinafter, embodiments of the disclosure will be described in detail with reference to the accompanying drawings.

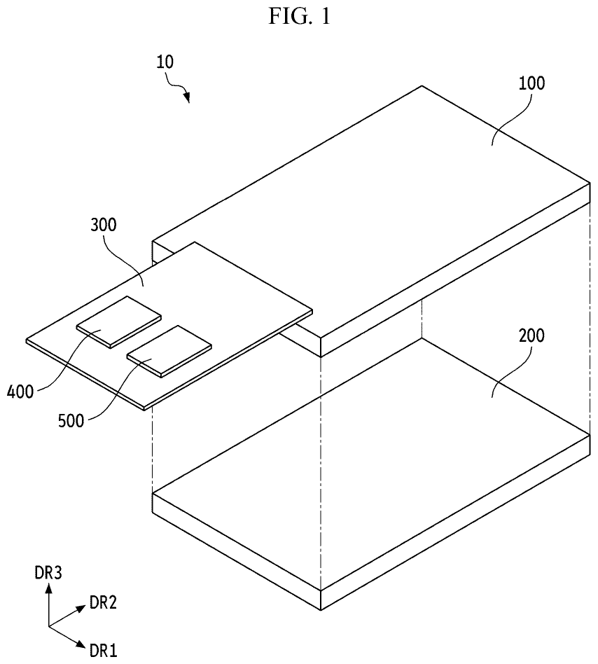

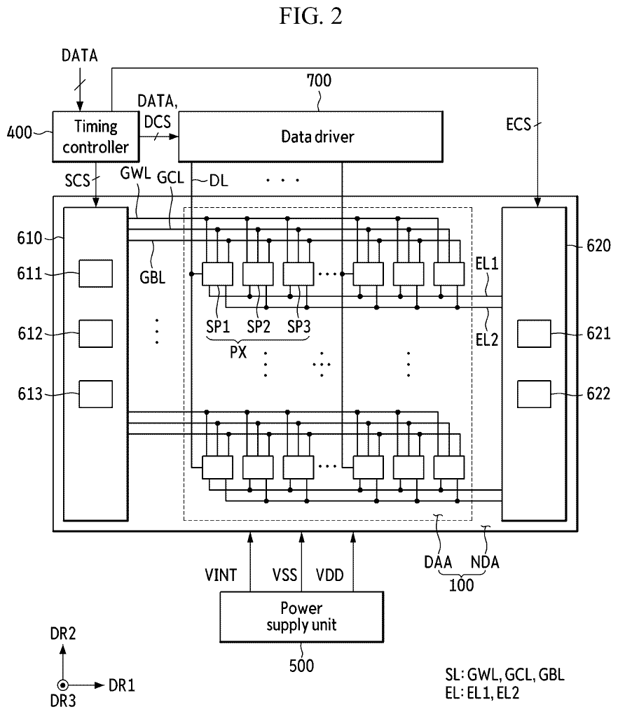

FIG. 1 is an exploded perspective view illustrating an embodiment of a display device. FIG. 2 is a block diagram illustrating an embodiment of the display device.

Referring to FIGS. 1 and 2, a display device 10 in an embodiment is a device that displays a moving image or a still image. The display device 10 in an embodiment may be applied to portable electronic devices such as mobile phones, smartphones, tablet personal computers (“PCs”), mobile communication terminals, electronic notebooks, electronic books, portable multimedia players (“PMPs”), navigation devices, and ultra mobile PCs (“UMPCs”). In an embodiment, the display device 10 according an embodiment may be applied as a display unit of televisions, laptop computers, monitors, billboards, or the Internet of Things (“IoTs”). In an alternative embodiment, the display device 10 according an embodiment may be applied to smart watches, watch phones, or head mounted displays (“HMDs”) for implementing virtual reality and augmented reality.

The display device 10 in an embodiment may include a display panel 100, a heat dissipation layer 200, a circuit board 300, a timing controller 400, and a power supply unit 500.

The display panel 100 may have a shape similar to a quadrangular shape, e.g., rectangular shape in a plan view. In an embodiment, the display panel 100 may have a shape similar to a quadrangular shape, e.g., rectangular shape, in a plan view, having short sides in a first direction DR1 and long sides in a second direction DR2 crossing the first direction DR1, for example. In the display panel 100, a corner where the short side in the first direction DR1 and the long side in the second direction DR2 meet may have a round shape so as to have a predetermined curvature or a right-angled shape. A shape of the display panel 100 in a plan view is not limited to the rectangular shape, and may be a shape similar to other polygonal shapes, a circular shape, or an elliptical shape. A shape of the display device 10 in a plan view may follow the shape of the display panel 100 in a plan view, but the disclosure is not limited thereto.

In the drawings, the first direction DR1 and the second direction DR2 are horizontal directions, respectively, and cross each other. For example, the first direction DR1 and the second direction DR2 may be orthogonal to each other. In addition, a third direction DR3 may be a perpendicular direction crossing, for example, orthogonal to, the first direction DR1 and the second direction DR2. Unless otherwise defined, directions indicated by arrows of the first to third directions DR1, DR2, and DR3 may be referred to as one side, and directions opposite to one side may be referred to as a remaining (the other) side. In addition, the terms “on”, “upper side”, “upper portion”, “top”, and “upper surface” as used herein refer to a direction toward which an arrow of the third direction DR3 is directed in the drawings, and the terms “below”, “lower side”, “lower portion”, “bottom”, and “lower surface” used as herein refer to a direction opposite to the direction toward which the arrow of the third direction DR3 is directed in the drawings.

The display panel 100 may include a display area DAA that displays an image and a non-display area NDA that does not display an image, as illustrated in FIG. 2.

The display area DAA may include a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1 and may be disposed in the second direction DR2. The plurality of data lines DL may extend in the second direction DR2 and may be disposed in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

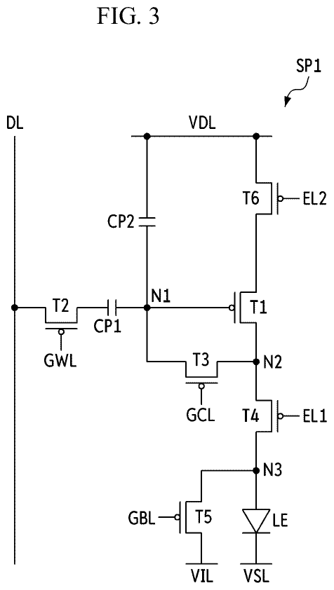

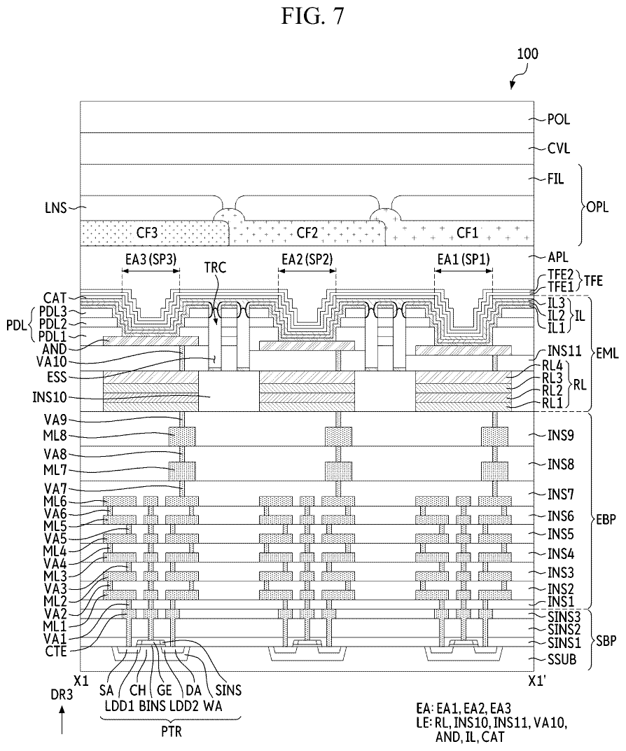

The plurality of pixels PX may include first to third sub-pixels SP1, SP2, and SP3. The first to third sub-pixels SP1, SP2, and SP3 may include a plurality of pixel transistors as illustrated in FIG. 3 to be described below, and the plurality of pixel transistors may be formed by a semiconductor process and disposed on a semiconductor substrate SSUB (refer to FIG. 7). In an embodiment, a plurality of pixel transistors of a data driver 700 may be configured as complementary metal oxide semiconductors (“CMOSs”), for example.

Each of the first to third sub-pixels SP1, SP2, and SP3 may be connected to any one of the plurality of write scan lines GWL, any one of the plurality of control scan lines GCL, any one of the plurality of bias scan lines GBL, any one of the plurality of first emission control lines EL1, any one of the plurality of second emission control lines EL2, and any one of the plurality of data lines DL. Each of the first to third sub-pixels SP1, SP2, and SP3 may receive a data voltage of the data line DL according to a write scan signal of the write scan line GWL, and allow a light-emitting element to emit light according to the data voltage.

The non-display area NDA may include a scan driver 610, an emission driver 620, and a data driver 700.

The scan driver 610 may include a plurality of scan transistors, and the emission driver 620 may include a plurality of emission transistors. The plurality of scan transistors and the plurality of emission transistors may be formed by a semiconductor process and disposed on the semiconductor substrate SSUB (refer to FIG. 7). In an embodiment, the plurality of scan transistors and the plurality of emission transistors may be configured as CMOSs, for example. It has been illustrated in FIG. 2 that the scan driver 610 is disposed on the left side of the display area DAA and the emission driver 620 is disposed on the right side of the display area DAA, but the disclosure is not limited thereto. In an embodiment, the scan drivers 610 and the emission drivers 620 may be disposed on both the left and right sides of the display area DAA, for example.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing controller 400. The write scan signal output unit 611 may generate write scan signals according to the scan timing control signal SCS of the timing controller 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines GBL.

The emission driver 620 may include a first emission control driver 621 and a second emission control driver 622. Each of the first emission control driver 621 and the second emission control driver 622 may receive an emission timing control signal ECS from the timing controller 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 may include a plurality of data transistors, and the plurality of data transistors may be formed by a semiconductor process and disposed on the semiconductor substrate SSUB (refer to FIG. 7). In an embodiment, the plurality of data transistors may be configured as CMOSs, for example.

The data driver 700 may receive digital video data DATA and a data timing control signal DCS from the timing controller 400. The data driver 700 may convert the digital video data DATA into analog data voltages according to the data timing control signal DCS and output the analog data voltages to the data lines DL. In this case, the sub-pixels SP1, SP2, and SP3 may be selected by the write scan signals of the scan driver 610, and the data voltages may be supplied to the selected sub-pixels SP1, SP2, and SP3.

The heat dissipation layer 200 may overlap the display panel 100 in the third direction DR3, which is a thickness direction of the display panel 100. The heat dissipation layer 200 may be disposed on one surface, e.g., a rear surface, of the display panel 100. The heat dissipation layer 200 may serve to dissipate heat generated from the display panel 100. The heat dissipation layer 200 may include a layer including or consisting of graphite or metal such as silver (Ag), copper (Cu), or aluminum (Al) having relatively high thermal conductivity.

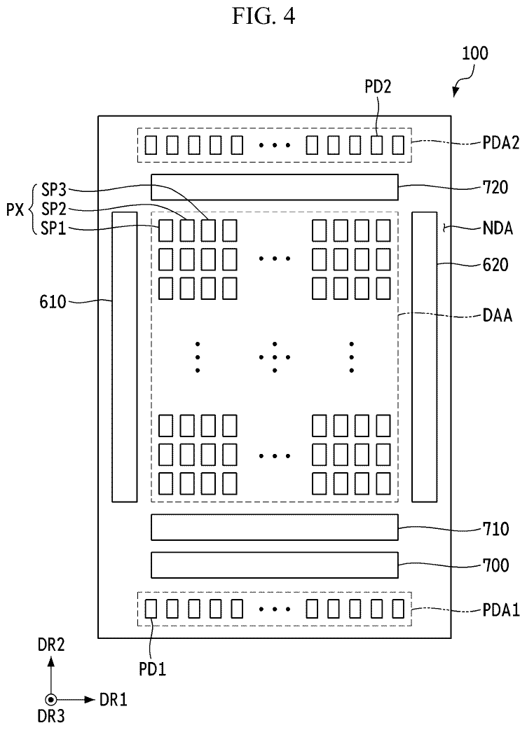

The circuit board 300 may be electrically connected to a plurality of first pads PD1 (refer to FIG. 4) of a first pad unit PDA1 (refer to FIG. 4) of the display panel 100 using a conductive adhesive member such as an anisotropic conductive film. The circuit board 300 may be a flexible printed circuit board or a flexible film having a flexible material. It has been illustrated in FIG. 1 that the circuit board 300 is unbent, but the circuit board 300 may be bent. In this case, one end of the circuit board 300 may be disposed on the rear surface of the display panel 100 and/or a rear surface of the heat dissipation layer 200. One end of the circuit board 300 may be an end opposite to an opposite end of the circuit board 300 connected to the plurality of first pads PD1 (refer to FIG. 4) of the first pad unit PDA1 (refer to FIG. 4) of the display panel 100 using the conductive adhesive member.

The timing controller 400 may receive digital video data and timing signals from the outside. The timing controller 400 may generate the scan timing control signal SCS, the emission timing control signal ECS, and the data timing control signal DCS for controlling the display panel 100 according to the timing signals. The timing controller 400 may output the scan timing control signal SCS to the scan driver 610 and output the emission timing control signal ECS to the emission driver 620. The timing controller 400 may output the digital video data and the data timing control signal DCS to the data driver 700.

The power supply unit 500 may generate a plurality of panel driving voltages according to an external source voltage. In an embodiment, the power supply unit 500 may generate a first driving voltage VSS, a second driving voltage VDD, and a third driving voltage VINT and supply the first driving voltage VSS, the second driving voltage VDD, and the third driving voltage VINT to the display panel 100, for example. The first driving voltage VSS, the second driving voltage VDD, and the third driving voltage VINT will be described later with reference to FIG. 3.

Each of the timing controller 400 and the power supply unit 500 may be configured as an integrated circuit (“IC”) and attached to one surface of the circuit board 300. In this case, the scan timing control signal SCS, the emission timing control signal ECS, the digital video data DATA, and the data timing control signal DCS of the timing controller 400 may be supplied to the display panel 100 through the circuit board 300. In addition, the first driving voltage VSS, the second driving voltage VDD, and the third driving voltage VINT of the power supply unit 500 may be supplied to the display panel 100 through the circuit board 300.

In an alternative embodiment, each of the timing controller 400 and the power supply unit 500 may be disposed in the non-display area NDA of the display panel 100, similar to the scan driver 610, the emission driver 620, and the data driver 700. In this case, the timing controller 400 may include a plurality of timing transistors, and the power supply unit 500 may include a plurality of power transistors. The plurality of timing transistors and the plurality of power transistors may be formed by a semiconductor process and disposed on the semiconductor substrate SSUB (refer to FIG. 7). In an embodiment, the plurality of timing transistors and the plurality of power transistors may be configured as CMOSs, for example. Each of the timing controller 400 and the power supply unit 500 may be disposed between the data driver 700 and the first pad unit PDA1 (refer to FIG. 4).

FIG. 3 is an equivalent circuit diagram of an embodiment of a first sub-pixel.

Referring to FIG. 3 in addition to FIGS. 1 and 2, the first sub-pixel SP1 may be connected to a write scan line GWL, a control scan line GCL, a bias scan line GBL, a first emission control line EL1, a second emission control line EL2, and a data line DL. In addition, the first sub-pixel SP1 may be connected to a first driving voltage line VSL to which the first driving voltage VSS corresponding to a relatively low potential voltage is applied, a second driving voltage line VDL to which the second driving voltage VDD corresponding to a relatively high potential voltage is applied, and a third driving voltage line VIL to which the third driving voltage VINT corresponding to an initialization voltage is applied That is, the first driving voltage line VSL may be a relatively low potential voltage line, the second driving voltage line VDL may be a relatively high potential voltage line, and the third driving voltage line VIL may be an initialization voltage line. In this case, the first driving voltage VSS may be a voltage lower than the third driving voltage VINT. The second driving voltage VDD may be a voltage higher than the third driving voltage VINT.

The first sub-pixel SP1 may include a plurality of transistors T1 to T6, a light-emitting element LE, a first capacitor CP1, and a second capacitor CP2.

The light-emitting element LE may emit light according to a driving current (source-drain current: I_{ds}) flowing through a channel of a first transistor T1. An amount of light emitted from the light-emitting element LE may be proportional to the driving current. The light-emitting element LE may be disposed between a fourth transistor T4 and the first driving voltage line VSL. A first electrode of the light-emitting element LE may be connected to a drain electrode of the fourth transistor T4, and a second electrode of the light-emitting element LE may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer disposed between the first electrode and the second electrode, but the disclosure is not limited thereto. In an embodiment, the light-emitting element LE may be an inorganic light-emitting element including a first electrode, a second electrode, and an inorganic semiconductor disposed between the first electrode and the second electrode, for example, and may be a micro light-emitting diode, for example.

The first transistor T1 may be a driving transistor controlling the driving current flowing between a source electrode and a drain electrode according to a voltage applied to a gate electrode thereof. The first transistor T1 may include the gate electrode connected to a first node N1, the source electrode connected to a drain electrode of a sixth transistor T6, and the drain electrode connected to a second node N2.

A second transistor T2 may be disposed between one electrode of the first capacitor CP1 and the data line DL. The second transistor T2 may be turned on by a write scan signal of the write scan line GWL to connect one electrode of the first capacitor CP1 to the data line DL. For this reason, a data voltage of the data line DL may be applied to one electrode of the first capacitor CP1. The second transistor T2 may include a gate electrode connected to the write scan line GWL, a source electrode connected to the data line DL, and a drain electrode connected to one electrode of the first capacitor CP1.

A third transistor T3 may be disposed between the first node N1 and the second node N2. The third transistor T3 may be turned on by a control scan signal of the control scan line GCL to connect the first node N1 to the second node N2. For this reason, the gate electrode and the drain electrode of the first transistor T1 are connected to each other, and thus, the first transistor T1 may operate like a diode. The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 may be turned on by a first emission control signal of the first emission control line EL1 to connect the second node N2 to the third node N3. For this reason, the driving current of the first transistor T1 may be supplied to the light-emitting element LE. The fourth transistor T4 may include a gate electrode connected to the first emission control line EL1, a source electrode connected to the second node N2, and the drain electrode connected to the third node N3.

A fifth transistor T5 may be disposed between the third node N3 and the third driving voltage line VIL. The fifth transistor T5 may be turned on by a bias scan signal of the bias scan line GBL to connect the third node N3 to the third driving voltage line VIL. For this reason, the third driving voltage VINT of the third driving voltage line VIL may be applied to the first electrode of the light-emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 may be turned on by a second emission control signal of the second emission control line EL2 to connect the source electrode of the first transistor T1 to the second driving voltage line VDL. For this reason, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and the drain electrode connected to the source electrode of the first transistor T1.

The first capacitor CP1 may be disposed between the first node N1 and the drain electrode of the second transistor T2. The first capacitor CP1 may include one electrode connected to the drain electrode of the second transistor T2 and a remaining (the other) electrode connected to the first node N1.

The second capacitor CP2 may be disposed between the gate electrode of the first transistor T1 and the second driving voltage line VDL. The second capacitor CP2 may include one electrode connected to the gate electrode of the first transistor T1 and a remaining (the other) electrode connected to the second driving voltage line VDL.

The first node N1 may be a contact point between the gate electrode of the first transistor T1, the drain electrode of the third transistor T3, a remaining (the other) electrode of the first capacitor CP1, and one electrode of the second capacitor CP2. The second node N2 may be a contact point between the drain electrode of the first transistor T1, the source electrode of the third transistor T3, and the source electrode of the fourth transistor T4. The third node N3 may be a contact point between the drain electrode of the fourth transistor T4, the source electrode of the fifth transistor T5, and the first electrode of the light-emitting element LE.

Each of the first to sixth transistors T1 to T6 may be a metal oxide semiconductor field effect transistor (“MOSFET”). In an embodiment, each of the first to sixth transistors T1 to T6 may be a P-type MOSFET, for example, but the disclosure is not limited thereto. Each of the first to sixth transistors T1 to T6 may be an N-type MOSFET. In an alternative embodiment, some of the first to sixth transistors T1 to T6 may be P-type MOSFETs, and remaining (the other) transistors of the first to sixth transistors T1 to T6 may be N-type MOSFETs.

It has been illustrated in FIG. 3 that the first sub-pixel SP1 includes six transistors T1 to T6 and two capacitors CP1 and CP2, but an equivalent circuit diagram of the first sub-pixel SP1 is not limited to that illustrated in FIG. 3. In an embodiment, the number of transistors and the number of capacitors in the first sub-pixel SP1 may be variously modified, for example.

In addition, an equivalent circuit diagram of a second sub-pixel SP2 and an equivalent circuit diagram of a third sub-pixel SP3 may be substantially the same as the equivalent circuit diagram of the first sub-pixel SP1 described with reference to FIG. 3. Therefore, a description of the equivalent circuit diagram of the second sub-pixel SP2 and the equivalent circuit diagram of the third sub-pixel SP3 is omitted in the disclosure.

FIG. 4 is a plan view illustrating an embodiment of a display panel.

Referring to FIG. 4 in addition to FIGS. 1 to 3, the display area DAA of the display panel 100 in an embodiment may include a plurality of pixels PX arranged in a matrix form, and the non-display area NDA of the display panel 100 may include a scan driver 610, an emission driver 620, a data driver 700, a first distribution circuit 710, a second distribution circuit 720, a first pad unit PDA1, and a second pad unit PDA2. An overlapping description of the pixels PX, the scan driver 610, and the emission driver 620 is omitted.

The first pad unit PDA1 may include a plurality of first pads PD1 connected to pads or bumps of the circuit board 300 through a conductive adhesive member. The first pad unit PDA1 may be disposed on a third side of the display area DAA. In an embodiment, the first pad unit PDA1 may be disposed on an opposite side of the display area DAA in the second direction DR2, for example. That is, the first pad unit PDA1 may be disposed on the lower side of the display area DAA.

The first pad unit PDA1 may be disposed outside the data driver 700 in the second direction DR2. That is, the first pad unit PDA1 may be disposed closer to an edge of the display panel 100 than the data driver 700 is.

The second pad unit PDA2 may include a plurality of second pads PD2 corresponding to inspection pads that inspect whether or not the display panel 100 operates normally. The plurality of second pads PD2 may be connected to a jig or a probe pin or connected to a circuit board for inspection in an inspection process. The circuit board for inspection may be a printed circuit board including or consisting of a rigid material or a flexible printed circuit board including or consisting of a flexible material.

The first distribution circuit 710 may distribute data voltages applied through the first pad unit PDA1 to the plurality of data lines DL. In an embodiment, the first distribution circuit 710 may distribute data voltages applied through one first pad PD1 of the first pad unit PDA1 to N data lines DL (N is a positive integer of 2 or more), and for this reason, the number of first pads PD1 may be reduced, for example. The first distribution circuit 710 may be disposed on the third side of the display area DAA of the display panel 100. In an embodiment, the first distribution circuit 710 may be disposed on an opposite side of the display area DAA in the second direction DR2, for example. That is, the first distribution circuit 710 may be disposed on the lower side of the display area DAA.

The second distribution circuit 720 may distribute signals applied through the second pad unit PDA2 to the scan driver 610, the emission driver 620, and the data lines DL. The second pad unit PDA2 and the second distribution circuit 720 may be components for inspecting an operation of each of the pixels PX of the display area DAA. The second distribution circuit 720 may be disposed on a fourth side of the display area DAA of the display panel 100. In an embodiment, the second distribution circuit 720 may be disposed on one side of the display area DAA in the second direction DR2, for example. That is, the second distribution circuit 720 may be disposed on the upper side of the display area DAA.

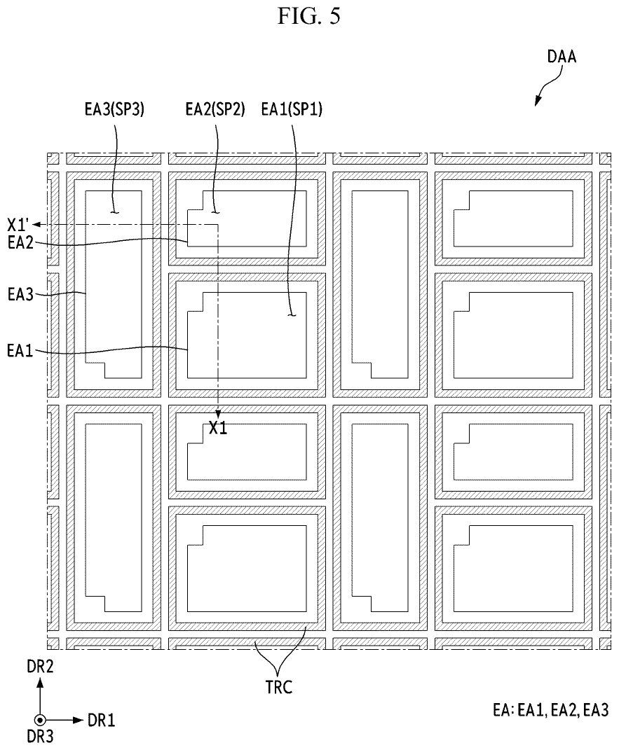

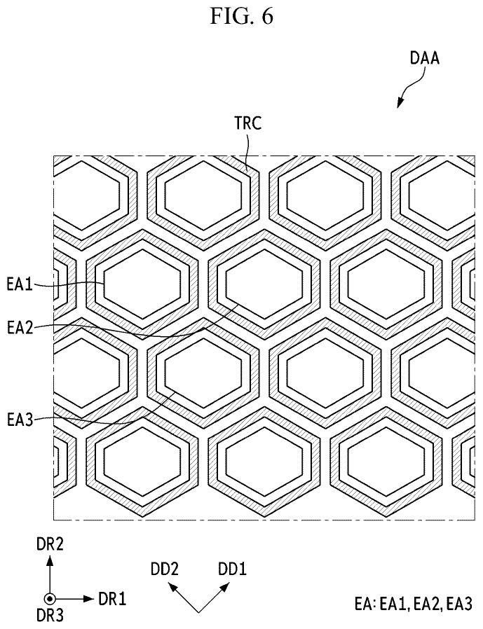

FIGS. 5 and 6 are plan views illustrating arrangements of a plurality of pixels in a display area of FIG. 4.

Referring to FIGS. 5 and 6, in a portion overlapping the display area DAA, each of the plurality of pixels PX may include a first emission area EA1 that is an emission area of the first sub-pixel SP1, a second emission area EA2 that is an emission area of the second sub-pixel SP2, and a third emission area EA3 that is an emission area of the third sub-pixel SP3.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. In an embodiment, the blue wavelength band may indicate that a main peak wavelength of the light is included in a wavelength band of approximately 370 nanometers (nm) to approximately 460 nm, the green wavelength band may indicate that a main peak wavelength of the light is included in a wavelength band of approximately 480 nm to approximately 560 nm, and the red wavelength band may indicate that a main peak wavelength of the light is included in a wavelength band of approximately 600 nm and approximately 750 nm, for example.

In some embodiments, emission areas EA may be disposed in a stripe structure in which they are arranged in the first direction DR1 and the second direction DR2 as illustrated in FIG. 5, a PenTile® structure having a diamond arrangement, or a hexagonal structure having a hexagonal shape in a plan view as illustrated in FIG. 6 However, the disclosure is not limited thereto, and the emission areas EA may have a structure in which other polygonal, circular, elliptical, or irregular shapes in a plan view are arranged, in addition to the above-described arrangement structure.

In some embodiments, when the emission areas EA have the stripe structure, the first emission area EA1 and the second emission area EA2 may neighbor to each other in the second direction DR2, and the first emission area EA1 and the third emission area EA3, and the second emission area EA2 and the third emission area EA3 may neighbor to each other in the first direction DR1. An area of the first emission area EA1, an area of the second emission area EA2, and an area of the third emission area EA3 may be different from each other.

In some embodiments, when the emission areas EA have the hexagonal structure, the first emission area EA1 and the second emission area EA2 may neighbor to each other in the first direction DR1, but the second emission area EA2 and the third emission area EA3 may neighbor to each other in a first diagonal direction DD1, and the first emission area EA1 and the third emission area EA3 may neighbor to each other in a second diagonal direction DD2. In this case, the first diagonal direction DD1 crosses each of the first direction DR1 and the second direction DR2, which are the horizontal directions. In an embodiment, the first diagonal direction DD1 may be a direction inclined by 45° with respect to each of the first direction DR1 and the second direction DR2, for example, but is not limited thereto. The second diagonal direction DD2 crosses each of the first direction DR1 and the second direction DR2, which are the horizontal directions. In an embodiment, the second diagonal direction DD2 may be a direction inclined by 45° with respect to each of a direction opposite to the first direction DR1 and the second direction DR2, for example, but is not limited thereto. The second diagonal direction DD2 may be a direction orthogonal to the first diagonal direction DD1.

It has been illustrated in FIGS. 5 and 6 that each of the plurality of pixels PX includes three emission areas EA, but the disclosure is not limited thereto. In an embodiment, each of the plurality of pixels PX may include four or more emission areas EA.

Each emission area EA included in the plurality of pixels PX may be surrounded by each trench TRC. The trench TRC will be described later.

FIG. 7 is a cross-sectional view illustrating an embodiment of the display panel taken along X1-X1′ of FIG. 5.

Referring to FIG. 7, the display panel 100 may include a semiconductor backplane SBP, a light-emitting element backplane EBP, a display element layer EML, an encapsulation layer TFE, an optical layer OPL, a cover layer CVL, and a polarizing plate POL.

The semiconductor backplane SBP may include a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be replaced with a glass substrate or a polymer resin substrate such as a polyimide substrate. In this case, thin film transistors may be disposed on the glass substrate or the polymer resin substrate. The glass substrate may be a rigid substrate that is not bent, and the polymer resin substrate may be a flexible substrate that may be bent or curved.

The semiconductor substrate SSUB may be a substrate doped with first-type impurities. A plurality of well regions WA may be disposed in an upper surface of the semiconductor substrate SSUB. The plurality of well regions WA may be regions doped with second-type impurities. The second-type impurities may be different from the first-type impurities described above. In an embodiment, when the first-type impurities are p-type impurities, the second-type impurities may be n-type impurities, for example. In an alternative embodiment, when the first-type impurities are n-type impurities, the second-type impurities may be p-type impurities.

Each of the plurality of well regions WA may include a source region SA corresponding to a source electrode of the pixel transistor PTR, a drain region DA corresponding to a drain electrode of the pixel transistor PTR, and a channel region CH disposed between the source region SA and the drain region DA.

A bottom insulating film BINS may be disposed between a gate electrode GE and the well region WA. Side surface insulating films SINS may be disposed on side surfaces of the gate electrode GE. The side surface insulating films SINS may be disposed on the bottom insulating film BINS.

Each of the source region SA and the drain region DA may be a region doped with the first-type impurities. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on an opposite side of the gate electrode GE.

Each of the plurality of well regions WA may further include a first low-concentration impurity region LDD1 disposed between the channel region CH and the source region SA and a second low-concentration impurity region LDD2 disposed between the channel region CH and the drain region DA. The first low-concentration impurity region LDD1 may be a region having a lower impurity concentration than the source region SA due to the bottom insulating film BINS. The second low-concentration impurity region LDD2 may be a region having a lower impurity concentration than the drain region DA due to the bottom insulating film BINS. A distance between the source region SA and the drain region DA may increase by the first low-concentration impurity region LDD1 and the second low-concentration impurity region LDD2. Therefore, a length of the channel region CH of each of the pixel transistors PTR increases, and thus, punch-through and hot carrier phenomena caused by a short channel is prevented.

A first semiconductor insulating film SINS1 may be disposed on the semiconductor substrate SSUB. The first semiconductor insulating film SINS1 may be formed as a silicon carbonitride (SiCN) or silicon oxide (SiOₓ)-based inorganic film, but the disclosure is not limited thereto.

A second semiconductor insulating film SINS2 may be disposed on the first semiconductor insulating film SINS1. The second semiconductor insulating film SINS2 may be formed as a silicon oxide (SiOₓ)-based inorganic film, but the disclosure is not limited thereto.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through a hole penetrating through the first semiconductor insulating film SINS1 and the second semiconductor insulating film SINS2. Each of the plurality of contact terminals CTE may include or consist of any one of copper (Cu), aluminum (Al), tungsten (W), molybdenum (Mo), chromium (Cr), gold (Au), titanium (Ti), nickel (Ni), and neodymium (Nd), or alloys thereof.

A third semiconductor insulating film SINS3 may be disposed on side surfaces of each of the plurality of contact terminals CTE. An upper surface of each of the plurality of contact terminals CTE may be exposed without being covered by the third semiconductor insulating film SINS3. The third semiconductor insulating film SINS3 may be formed as a silicon oxide (SiOₓ)-based inorganic film, but the disclosure is not limited thereto.

The light-emitting element backplane EBP may include a plurality of conductive layers ML1 to ML8, a plurality of vias VA1 to VA9, and a plurality of insulating films INS1 to INS9.

First to eighth conductive layers ML1 to ML8 serve to implement a pixel circuit of the first sub-pixel SP1 illustrated in FIG. 3 by connecting the plurality of contact terminals CTE exposed from the semiconductor backplane SBP to each other. In an embodiment, only the first to sixth transistors T1 to T6 are formed in the semiconductor backplane SBP, and connection lines of the first to sixth transistors T1 to T6 and the first capacitor CP1 and the second capacitor CP2 may be disposed in the first to eighth conductive layers ML1 to ML8, for example. In addition, a connection portion between a drain region corresponding to the drain electrode of the fourth transistor T4, a source region corresponding to the source electrode of the fifth transistor T5, and the first electrode of the light-emitting element LE may also be disposed in the first to eighth conductive layers ML1 to ML8.

A first insulating film INS1 may be disposed on the semiconductor backplane SBP. Each of first vias VA1 may penetrate through the first film INS1 to be connected to the contact terminal CTE exposed from the semiconductor backplane SBP. Each of the first conductive layers ML1 may be disposed on the first insulating film INS1 and connected to the first via VA1.

A second insulating film INS2 may be disposed on the first insulating film INS1 and the first conductive layers ML1. Each of second vias VA2 may penetrate through the second insulating film INS2 to be connected to the exposed first conductive layer ML1. Each of the second conductive layers ML2 may be disposed on the second insulating film INS2 and connected to the second via VA2.

A third insulating film INS3 may be disposed on the second insulating film INS2 and the second conductive layers ML2. Each of third vias VA3 may penetrate through the third insulating film INS3 to be connected to the exposed second conductive layer ML2. Each of the third conductive layers ML3 may be disposed on the third insulating film INS3 and connected to the third via VA3.

A fourth insulating film INS4 may be disposed on the third insulating film INS3 and the third conductive layer ML3. Each of fourth vias VA4 may penetrate through the fourth insulating film INS4 to be connected to the exposed third conductive layer ML3. Each of the fourth conductive layers ML4 may be disposed on the fourth insulating film INS4 and connected to the fourth via VA4.

A fifth insulating film INS4 may be disposed on the fourth insulating film INS4 and the fourth conductive layers ML4. Each of fifth vias VA5 may penetrate through the fifth film INS5 to be connected to the exposed fourth conductive layer ML4. Each of the fifth conductive layers ML5 may be disposed on the fifth insulating film INS5 and connected to the fifth via VA5.

A sixth insulating film INS6 may be disposed on the fifth insulating film INS5 and the fifth conductive layer ML5. Each of sixth vias VA6 may penetrate through the sixth insulating film INS6 to be connected to the exposed fifth conductive layer ML5. Each of the sixth conductive layers ML6 may be disposed on the sixth insulating film INS6 and connected to the sixth via VA6.

A seventh insulating film INS7 may be disposed on the sixth insulating film INS6 and the sixth conductive layer ML6. Each of seventh vias VA7 may penetrate through the seventh insulating film INS7 to be connected to the exposed sixth conductive layer ML6. Each of the seventh conductive layers ML7 may be disposed on the seventh insulating film INS7 and connected to the seventh via VA7.

An eighth insulating film INS8 may be disposed on the seventh insulating film INS7 and the seventh conductive layer ML7. Each of eighth vias VA8 may penetrate through the eighth insulating film INS8 to be connected to the exposed seventh conductive layer ML7. Each of the eighth conductive layers ML8 may be disposed on the eighth insulating film INS8 and connected to the eighth via VA8.

The first to eighth conductive layers ML1 to ML8 and the first to eighth vias VA1 to VA8 may include or consist of substantially the same material as each other. Each of the first to eighth conductive layers ML1 to ML8 and the first to eighth vias VA1 to VA8 may include or consist of any one of copper (Cu), aluminum (Al), tungsten (W), molybdenum (Mo), chromium (Cr), gold (Au), titanium (Ti), nickel (Ni), and neodymium (Nd), or alloys thereof. The first to eighth insulating films INS1 to INS8 may be formed as silicon oxide (SiOₓ)-based inorganic films, but the disclosure is not limited thereto.

Each of a thickness of the first conductive layer ML1, a thickness of the second conductive layer ML2, a thickness of the third conductive layer ML3, a thickness of the fourth conductive layer ML4, a thickness of the fifth conductive layer ML5, and a thickness of the sixth conductive layer ML6 may be greater than each of a thickness of the first via VA1, a thickness of the second via VA2, a thickness of the third via VA3, a thickness of the fourth via VA4, a thickness of the fifth via VA5, and a thickness of the sixth via VA6. Each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same as each other. In an embodiment, the thickness of the first conductive layer ML1 is approximately 1360 Å, each of the thickness of the second conductive layer ML2, the thickness of the third conductive layer ML3, the thickness of the fourth conductive layer ML4, the thickness of the fifth conductive layer ML5, and the thickness of the sixth conductive layer ML6 is approximately 1440 Å, and each of the thickness of the first via VA1, the thickness of the second via VA2, the thickness of the third via VA3, the thickness of the fourth via VA4, the thickness of the fifth via VA5, and the thickness of the sixth via VA6 is approximately 1150 Å, for example. However, the thicknesses of the first to sixth conductive layers ML1, ML2, ML3, ML4, ML5, and ML6 and the first to sixth vias VA1, VA2, VA3, VA4, VA5, and VA6 are not limited thereto.

Each of a thickness of the seventh conductive layer ML7 and a thickness of the eighth conductive layer ML8 may be greater than each of the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. Each of the thickness of the seventh conductive layer ML7 and the eighth conductive layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same as each other. In an embodiment, each of the thickness of the seventh conductive layer ML7 and the eighth conductive layer ML8 is approximately 9000 Å, and each of the thickness of the seventh via VA7 and the thickness of the eighth via VA8 is approximately 6000 Å, for example. However, the thicknesses of the seventh conductive layer ML7, the eighth conductive layer ML8, the seventh via VA7, and the eighth via VA8 are not limited thereto.

A ninth insulating film INS9 may be disposed on the eighth insulating film INS8 and the eighth conductive layer ML8. The ninth insulating film INS9 may be formed as a silicon oxide (SiOₓ)-based inorganic film, but the disclosure is not limited thereto.

Each of ninth vias VA9 may penetrate through the ninth insulating film INS9 to be connected to the exposed eighth conductive layer ML8. Each of the ninth vias VA9 may include or consist of any one of copper (Cu), aluminum (Al), tungsten (W), molybdenum (Mo), chromium (Cr), gold (Au), titanium (Ti), nickel (Ni), and neodymium (Nd), or alloys thereof.

The display element layer EML may be disposed on the light-emitting element backplane EBP. The display element layer EML may include light-emitting elements LE, a pixel defining film PDL, and a plurality of trenches TRC. Each of the light-emitting elements LE may include a reflective electrode layer RL, tenth and eleventh insulating films INS10 and INS11, a tenth via VA10, a first electrode AND, a light-emitting layer IL, and a second electrode CAT.

The reflective electrode layer RL may be disposed on the ninth insulating film INS9. The reflective electrode layer RL may include one or more reflective electrodes RL1, RL2, RL3, and RL4. In an embodiment, the reflective electrode layer RL may include first to fourth reflective electrodes RL1, RL2, RL3, and RL4 as illustrated in FIG. 7, for example, but is not limited thereto.

Each of the first reflective electrodes RL1 may be disposed on the ninth insulating film INS9 and connected to the ninth via VA9. Each of the first reflective electrodes RL1 may include or consist of any one of copper (Cu), aluminum (Al), tungsten (W), molybdenum (Mo), chromium (Cr), gold (Au), titanium (Ti), nickel (Ni), and neodymium (Nd), or alloys thereof. In an embodiment, each of the first reflective electrodes RL1 may include titanium nitride (TiN), for example.

Each of the second reflective electrodes RL2 may be disposed on the first reflective electrode RL1. Each of the second reflective electrodes RL2 may include or consist of any one of copper (Cu), aluminum (Al), tungsten (W), molybdenum (Mo), chromium (Cr), gold (Au), titanium (Ti), nickel (Ni), and neodymium (Nd), or alloys thereof. In an embodiment, each of the second reflective electrodes RL2 may include aluminum (Al), for example.

Each of the third reflective electrodes RL3 may be disposed on the second reflective electrode RL2. Each of the third reflective electrodes RL3 may include or consist of any one of copper (Cu), aluminum (Al), tungsten (W), molybdenum (Mo), chromium (Cr), gold (Au), titanium (Ti), nickel (Ni), and neodymium (Nd), or alloys thereof. In an embodiment, each of the third reflective electrodes RL3 may include titanium nitride (TiN), for example.

Each of the fourth reflective electrodes RL4 may be disposed on the third reflective electrode RL3. Each of the fourth reflective electrodes RL4 may include or consist of any one of copper (Cu), aluminum (Al), tungsten (W), molybdenum (Mo), chromium (Cr), gold (Au), titanium (Ti), nickel (Ni), and neodymium (Nd), or alloys thereof. In an embodiment, each of the fourth reflective electrodes RL4 may include titanium (Ti), for example.

Since the second reflective electrodes RL2 are electrodes substantially reflecting light from the light-emitting elements LE, a thickness of the second reflective electrode RL2 may be greater than a thickness of the first reflective electrode RL1, a thickness of the third reflective electrode RL3, and a thickness of the fourth reflective electrode RL4. In an embodiment, each of the thickness of the first reflective electrode RL1, the third reflective electrode RL3, and the fourth reflective electrode RL4 is approximately 100 Å, and the thickness of the second reflective electrode RL2 is approximately 850 Å, for example. However, the thicknesses of the first to fourth reflective electrodes RL1, RL2, RL3, and RL4 are not limited thereto.

The tenth insulating film INS10 may be disposed on the ninth insulating film INS9. The tenth insulating film INS10 may be disposed between the reflective electrode layers RL next (adjacent) to each other in a horizontal direction. The tenth insulating film INS10 may be formed as a silicon oxide (SiOₓ)-based inorganic film, but the disclosure is not limited thereto. In some embodiments, although not illustrated in FIG. 7, the tenth insulating film INS10 may be disposed not only between the reflective electrode layers RL but also on the reflective electrode layer RL.

The eleventh insulating film INS11 may be disposed on the tenth insulating film INS10 and the reflective electrode layer RL. The eleventh insulating film INS11 may be formed as a silicon oxide (SiOₓ)-based inorganic film, but the disclosure is not limited thereto. The tenth insulating film INS10 and the eleventh insulating film INS11 may be optical auxiliary layers through which light reflected by the reflective electrode layer RL among light emitted from the light-emitting elements LE passes.

In some embodiment, in at least one of the first sub-pixel SP1, the second sub-pixel SP2, and the third sub-pixel SP3, total thicknesses of the insulating films disposed between the first electrodes AND the reflective electrode layers RL of the first sub-pixel SP1, the second sub-pixel SP2, and the third sub-pixel SP3 may be different from each other in order adjust a resonance distance of the light emitted from the light-emitting elements LE.

In an embodiment, as illustrated in FIG. 7, when the tenth insulating film INS10 is not disposed between the first electrode AND the reflective electrode layer RL and the eleventh insulating film INS11 is disposed between the first electrode AND the reflective electrode layer RL, thicknesses of the eleventh insulating films INS11 respectively disposed in the first sub-pixel SP1, the second sub-pixel SP2, and the third sub-pixel SP3 may be different from each other. In an embodiment, a thickness of the eleventh insulating film INS11 disposed in the first sub-pixel SP1 may be smaller than a thickness of the eleventh insulating film INS11 disposed in the second sub-pixel SP2, and the thickness of the eleventh insulating film INS11 disposed in the second sub-pixel SP2 may be smaller than a thickness of the eleventh insulating film INS11 disposed in the third sub-pixel SP3, for example.

In another embodiment, both the tenth insulating film INS10 and the eleventh insulating film INS11 may not be disposed between the first electrode AND the reflective electrode layer RL in the first sub-pixel SP1, any one of the tenth insulating film INS10 and the eleventh insulating film INS11 may be disposed between the first electrode AND the reflective electrode layer RL in the second sub-pixel SP2, and both the tenth insulating film INS10 and the eleventh insulating film INS11 may be disposed between the first electrode AND the reflective electrode layer RL in the third sub-pixel SP3.

In another embodiment, a twelfth insulating film may be further disposed between the first electrode AND the reflective electrode layer RL. In this case, any one of the tenth insulating film INS10, the eleventh insulating film INS11, and the twelfth insulating film may be disposed between the first electrode AND the reflective electrode layer RL in the first sub-pixel SP1, any two of the tenth insulating film INS10, the eleventh insulating film INS11, and the twelfth insulating film may be disposed between the first electrode AND the reflective electrode layer RL in the second sub-pixel SP2, and all of the tenth insulating film INS10, the eleventh insulating film INS11, and the twelfth insulating film may be disposed between the first electrode AND the reflective electrode layer RL in the third sub-pixel SP3.

In summary, a distance between the first electrode AND the reflective electrode layer RL may be different in each of the first sub-pixel SP1, the second sub-pixel SP2, and the third sub-pixel SP3. That is, in order to adjust a distance from the reflective electrode layer RL to the second electrode CAT according to a main wavelength of light emitted from each of the first sub-pixel SP1, the second sub-pixel SP2, and third the sub-pixel SP3, the presence or absence or thicknesses of the tenth inter-insulating film INS10 and the eleventh inter-insulating film INS11 may be set in each of the first sub-pixel SP1, the second sub-pixel SP2, and the third sub-pixel SP3.

It has been illustrated in FIG. 7 that the total thicknesses of the insulating films disposed between the first electrodes AND the reflective electrode layers RL are greater in the order of the first sub-pixel SP1, the second sub-pixel SP2, and the third sub-pixel SP3, but the disclosure is not limited thereto. That is, it has been illustrated that a distance between the first electrode AND the reflective electrode layer RL in the third sub-pixel SP3 is greater than a distance between the first electrode AND the reflective electrode layer RL in the second sub-pixel SP2 and a distance between the first electrode AND the reflective electrode layer RL in the first sub-pixel SP1 and the distance between the first electrode AND the reflective electrode layer RL in the second sub-pixel SP2 is greater than the distance between the first electrode AND the reflective electrode layer RL in the first sub-pixel SP1, but the disclosure is not limited thereto. A size relationship between the total thicknesses of the insulating films between the first electrodes AND the reflective electrode layers RL in the first sub-pixel SP1, the second sub-pixel SP2, and the third sub-pixel SP3 may be variously modified depending on the resonance distance.

Each of the tenth vias VA10 may penetrate through the eleventh insulating film INS11. Each of the tenth vias VA10 may include or consist of any one of copper (Cu), aluminum (Al), tungsten (W), molybdenum (Mo), chromium (Cr), gold (Au), titanium (Ti), nickel (Ni), and neodymium (Nd), or alloys thereof. A thickness of the tenth via VA10 in the second sub-pixel SP2 may be smaller than a thickness of the tenth via VA10 in the third sub-pixel SP3, and a thickness of the tenth via VA10 in the first sub-pixel SP1 may be smaller than the thickness of the tenth via VA10 in the second sub-pixel SP2, but the disclosure is not limited thereto.

The first electrode AND of each of the light-emitting elements LE may be disposed on the eleventh insulating film INS11 and connected to the tenth via VA10. The first electrode AND of each of the light-emitting elements LE may be connected to the drain region DA or the source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may include or consist of any one of copper (Cu), aluminum (Al), tungsten (W), molybdenum (Mo), chromium (Cr), gold (Au), titanium (Ti), nickel (Ni), and neodymium (Nd), or alloys thereof. In an embodiment, the first electrode AND of each of the light-emitting elements LE may include or consist of titanium nitride (TiN), for example.

The pixel defining film PDL may be disposed on a partial area of the first electrode AND of each of the light-emitting elements LE. The pixel defining film PDL may cover an edge of the first electrode AND of each of the light-emitting elements LE. The pixel defining film PDL serves to partition the respective first emission areas EA1, second emission areas EA2, and third emission areas EA3.

The first emission area EA1 may be defined as an area where the first electrode AND, the light-emitting layer IL, and the second electrode CAT are sequentially stacked in the first sub-pixel SP1 to emit light. The second emission area EA2 may be defined as an area where the first electrode AND, the light-emitting layer IL, and the second electrode CAT are sequentially stacked in the second sub-pixel SP2 to emit light. The third emission area EA3 may be defined as an area where the first electrode AND, the light-emitting layer IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed as silicon oxide (SiOₓ)-based inorganic films, but the disclosure is not limited thereto. Each of a thickness of the first pixel defining film PDL1, a thickness of the second pixel defining film PDL2, and a thickness of the third pixel defining film PDL3 may be approximately 500 Å.

When the first pixel defining film PDL1, the second pixel defining film PDL2, and the third pixel defining film PDL3 are formed as one pixel defining film, a height of the one pixel defining film increases, such that a first encapsulation layer TFE1 may be disconnected due to step coverage. The step coverage refers to a ratio of a degree at which a thin film is coated on an inclined portion to a degree at which a thin film is coated on a flat portion. The lower the step coverage, the more likely it is that the thin film will be disconnected at the inclined portion.

Therefore, in order to prevent the first encapsulation layer TFE1 from being disconnected due to the step coverage, the first pixel defining film PDL1, the second pixel defining film PDL2, and the third pixel defining film PDL3 may have a cross-sectional structure with a step having a staircase shape. In an embodiment, a width of the first pixel defining film PDL1 may be greater than a width of the second pixel defining film PDL2 and a width of the third pixel defining film PDL3, and the width of the second pixel defining film PDL2 may be greater than the width of the third pixel defining film PDL3, for example. The width of the first pixel defining film PDL1, the width of the second pixel defining film PDL2, and the width of the third pixel defining film PDL3 refer to a length of the first pixel defining film PDL1, a length of the second pixel defining film PDL2, and a length of the third pixel defining film PDL3 in the horizontal direction perpendicular to the third direction DR3, respectively.

Each of the plurality of trenches TRC may penetrate through the first pixel defining film PDL1, the second pixel defining film PDL2, and the third pixel defining film PDL3. In addition, each of the plurality of trenches TRC may penetrate through the eleventh insulating film INS11. In each of the plurality of trenches TRC, the eleventh insulating film INS11 may have a shape in which a portion thereof is trenched.

At least one trench TRC may be disposed between the first to third sub-pixels SP1, SP2, and SP3 neighboring to each other. It has been illustrated in FIG. 7 that two trenches TRC are disposed between the first to third sub-pixels SP1, SP2, and SP3 neighboring to each other, but the disclosure is not limited thereto.

The light-emitting layer IL may include a plurality of intermediate layers. It has been illustrated in FIG. 7 that the light-emitting layer IL has a three-tandem structure including a first stack layer IL1, a second stack layer IL2, and a third stack layer IL3, but the disclosure is not limited thereto. In an embodiment, the light-emitting layer IL may have a two-tandem structure including two intermediate layers, for example.

In the three-tandem structure, the light-emitting layer IL may have a tandem structure including a plurality of first to third stack layers IL1, IL2, and IL3 emitting different light. In an embodiment, the light-emitting layer IL may include the first stack layer IL1 emitting light of a first color, the second stack layer IL2 emitting light of a third color, and the third stack layer IL3 emitting light of a second color, for example. The first stack layer IL1, the second stack layer IL2, and the third stack layer IL3 may be sequentially stacked.

The first stack layer IL1 may have a structure in which a first hole transporting layer, a first organic light-emitting layer emitting the light of the first color, and a first electron transporting layer are sequentially stacked. The second stack layer IL2 may have a structure in which a second hole transporting layer, a second organic light-emitting layer emitting the light of the third color, and a second electron transporting layer are sequentially stacked. The third stack layer IL3 may have a structure in which a third hole transporting layer, a third organic light-emitting layer emitting the light of the second color, and a third electron transporting layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer supplying electrons to the first stack layer IL1 and a P-type charge generation layer supplying holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer supplying electrons to the second stack layer IL2 and a P-type charge generation layer supplying holes to the third stack layer IL3.

The first stack layer IL1 may be disposed on the first electrodes AND the pixel defining film PDL, and may be disposed on a bottom surface of each of the trenches TRC. Due to the trenches TRC, the first stack layer IL1 may be disconnected between the first to third sub-pixels SP1, SP2, and SP3 neighboring to each other. The second stack layer IL2 may be disposed on the first stack layer IL1. Due to the trenches TRC, the second stack layer IL2 may be disconnected between the first to third sub-pixels SP1, SP2, and SP3 neighboring to each other. A cavity ESS or an empty space may be disposed between the first stack layer IL1 and the second stack layer IL2. The third stack layer IL3 may be disposed on the second stack layer IL2. The third stack layer IL3 may not be disconnected by the trenches TRC, and may be disposed to cover the second stack layer IL2 in each of the trenches TRC. That is, in the three-tandem structure, each of the plurality of trenches TRC may be a structure for disconnecting the first and second stack layers IL1 and IL2, the first charge generation layer, and the second charge generation layer of the display element layer EML between the first to third sub-pixels SP1, SP2, and SP3 neighboring to each other. In addition, in the two-tandem structure, each of the plurality of trenches TRC may be a structure for disconnecting a charge generation layer disposed between a lower intermediate layer and an upper intermediate layer and the lower intermediate layer.

A height of each of the plurality of trenches TRC may be greater than a height of the pixel defining film PDL. This may be for stably disconnecting the first and second stack layers IL1 and IL2 of the display element layer EML between the first to third sub-pixels SP1, SP2, and SP3 neighboring to each other.

The height of each of the plurality of trenches TRC refers to a length of each of the plurality of trenches TRC in the third direction DR3. The height of the pixel defining film PDL refers to a length of the pixel defining film PDL in the third direction DR3. In order to disconnect the first and second stack layers IL1 and IL2 of the display element layer EML between the first to third sub-pixels SP1, SP2, and SP3 neighboring to each other, other structures may exist instead of the trenches TRC. In an embodiment, instead of the trenches TRC, partition walls having a reverse tapered shape may be disposed on the pixel defining film PDL, for example.

The number of first to third stack layers IL1, IL2, and IL3 emitting the different light is not limited to that illustrated in FIG. 7. In an embodiment, the light-emitting layer IL may include two intermediate layers. In this case, any one of the two intermediate layers may be substantially the same as the first stack layer IL1, and a remaining (the other) one of the two intermediate layers may include a second hole transporting layer, a second organic light-emitting layer, a third organic light-emitting layer, and a second electron transporting layer, for example. In this case, a charge generation layer for supplying electrons to any one intermediate layer and supplying charges to a remaining (the other) intermediate layer may be disposed between the two intermediate layers.

It has been illustrated in FIG. 7 that the first to third stack layers IL1, IL2, and IL3 are disposed in all of the first emission area EA1, the second emission area EA2, and the third emission area EA3, but the disclosure is not limited thereto. In an embodiment, the first stack layer IL1 may be disposed in the first emission area EA1, and may not be disposed in the second emission area EA2 and the third emission area EA3, for example. In addition, the second stack layer IL2 may be disposed in the second emission area EA2, and may not be disposed in the first emission area EA1 and the third emission area EA3. In addition, the third stack layer IL3 may be disposed in the third emission area EA3, and may not be disposed on the first emission area EA1 and the second emission area EA2. In this case, first to third color filters CF1, CF2, and CF3 of the optical layer OPL may be omitted.

The second electrode CAT may be disposed on the third stack layer IL3. The second electrode CAT may be disposed on the third stack layer IL3 in each of the plurality of trenches TRC.

The second electrode CAT may include or consist of a transparent conductive material (“TCO”) such as indium tin oxide (“ITO”) or indium zinc oxide (“IZO”) capable of transmitting light therethrough or a semi-transmissive conductive material such as magnesium (Mg), silver (Ag), or an alloy of magnesium (Mg) and silver (Ag). When the second electrode CAT includes or consists of the semi-transmissive conductive material, light emission efficiency of each of the first to third sub-pixels SP1, SP2, and SP3 may be increased by a micro cavity.

The encapsulation layer TFE may be disposed on the display element layer EML. The encapsulation layer TFE may include at least one inorganic film TFE1 or TFE2 in order to prevent oxygen or moisture from permeating into the display element layer EML. In an embodiment, the encapsulation layer TFE may include a first encapsulation layer TFE1 and a second encapsulation layer TFE2, for example.

The first encapsulation layer TFE1 may be disposed on the second electrode CAT. The first encapsulation layer TFE1 may be formed as multiple films in which one or more inorganic films of a silicon nitride (SiNₓ) film, a silicon oxynitride (SiON) film, and a silicon oxide (SiOₓ) film are alternately stacked. The first encapsulation layer TFE1 may be formed by a chemical vapor deposition (“CVD”) process.

The second encapsulation layer TFE2 may be disposed on the first encapsulation layer TFE1. The second encapsulation layer TFE2 may be formed as a titanium oxide (TiOₓ) layer or an aluminum oxide (AlOₓ) layer, but the disclosure is not limited thereto. The second encapsulation layer TFE2 may be formed by an atomic layer deposition (“ALD”) process. A thickness of the second encapsulation layer TFE2 may be smaller than a thickness of the first encapsulation layer TFE1.

The display panel 100 may further include an organic film APL. The organic film APL may be a layer for increasing interfacial adhesive strength between the encapsulation layer TFE and the optical layer OPL.

The organic film APL may be an organic film including or consisting of an acrylic resin, an epoxy resin, a phenolic resin, a polyamide resin, a polyimide resin, or the like.

The optical layer OPL may include a plurality of first to third color filters CF1, CF2, and CF3, a plurality of lenses LNS, and a filling layer FIL.

The first to third color filters CF1, CF2, and CF3 may be disposed on the organic film APL.

The first color filter CF1 may overlap the first emission area EA1 of the first sub-pixel SP1. The first color filter CF1 may transmit the light of the first color, that is, the light of the red wavelength band, therethrough. The red wavelength band may be a wavelength band of approximately 600 nm to approximately 750 nm. Therefore, the first color filter CF1 may transmit the light of the first color among light emitted from the first emission area EA1 therethrough.

The second color filter CF2 may overlap the second emission area EA2 of the second sub-pixel SP2. The second color filter CF2 may transmit the light of the second color, that is, the light of the green wavelength band, therethrough. The green wavelength band may be a wavelength band of approximately 480 nm to approximately 560 nm. Therefore, the second color filter CF2 may transmit the light of the second color among light emitted from the second emission area EA2 therethrough.

The third color filter CF3 may overlap the third emission area EA3 of the third sub-pixel SP3. The third color filter CF3 may transmit the light of the third color, that is, the light of the blue wavelength band, therethrough. The blue wavelength band may be a wavelength band of approximately 370 nm to approximately 460 nm. Therefore, the third color filter CF3 may transmit the light of the third color among light emitted from the third emission area EA3 therethrough.

Each of the plurality of lenses LNS may be disposed on each of the first color filter CF1, the second color filter CF2, and the third color filter CF3. Each of the plurality of lenses LNS may be a structure for increasing a ratio of light directed to a front surface of the display device 10. Each of the plurality of lenses LNS may have a cross-sectional shape convex in an upward direction. In some embodiments, the plurality of lenses LNS may be a micro lens array (“MLA”).

The filling layer FIL may be disposed on the plurality of lenses LNS. The filling layer FIL may have a predetermined refractive index so that light travels in the third direction DR3 at an interface between the plurality of lenses LNS and the filling layer FIL. In addition, the filling layer FIL may be a planarizing layer. The filling layer FIL may be an organic film including or consisting of an acrylic resin, an epoxy resin, a phenolic resin, a polyamide resin, a polyimide resin, or the like.

The cover layer CVL may be disposed on the filling layer FIL. The cover layer CVL may be a glass substrate or a polymer resin such as a resin. When the cover layer CVL is the glass substrate, the cover layer CVL may be attached onto the filling layer FIL. In this case, the filling layer FIL serves to adhere the cover layer CVL. When the cover layer CVL is the glass substrate, the cover layer CVL may serve as an encapsulation substrate. When the cover layer CVL is the polymer resin such as the resin, the cover layer CVL may be directly applied onto the filling layer FIL.

The polarizing plate POL may be disposed on one surface of the cover layer CVL. The polarizing plate POL may be a structure for preventing deterioration in visibility due to external light reflection. The polarizing plate POL may include a linear polarizing plate and a phase retardation film. In an embodiment, the phase retardation film may be a λ/4 plate (quarter-wave plate), for example, but the disclosure is not limited thereto. However, when visibility due to external light reflection is sufficiently improved by the first to third color filters CF1, CF2, and CF3, the polarizing plate POL may be omitted.

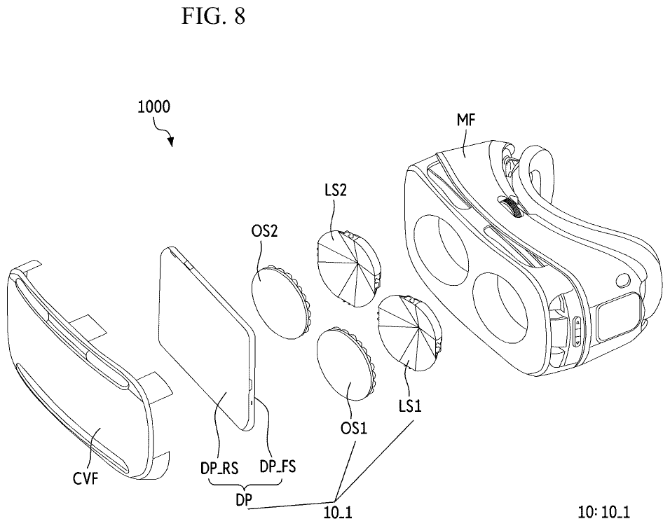

FIG. 8 is an exploded perspective view illustrating an embodiment of a head mounted display device.

Referring to FIG. 8, a head mounted display device 1000 is formed in a glasses form or a head mounted form and provides an image to a user using a display device 10_1.

The head mounted display device 1000 may include a see-through type that provides augmented reality based on actual external objects, and a see-closed type that provides virtual reality to a user with a screen independent of external objects.

The head mounted display device 1000 may include a main frame MF mounted on a user's body, the display device 10_1 mounted on the main frame MF and displaying an image, and a cover frame CF covering the display device 10_1.

The display device 10_1 may be formed integrally with the head mounted display device 1000 that the user may carry and easily mount on or demount from his/her face or head or may be formed in a form in which it is assembled to the head mounted display device 1000. The display device 10_1 may be substantially the same as the display device 10 described with reference to FIG. 1 or the like.

The display device 10_1 may include a display panel DP displaying an image, first and second lens frames OS1 and OS2 for refracting image display light, and first and second multi-channel lenses LS1 and LS2 forming light paths so that the image display light of the display panel DP is visible to the user.

The main frame MF may be worn on the user's face and head. The main frame MF may be formed in a shape corresponding to a structure of the user's head and face.

The display device 10_1, that is, the display panel DP, the first and second lens frames OS1 and OS2, and the first and second multi-channel lenses LS1 and LS2 may be formed integrally with the main frame MF. In an alternative embodiment, the display panel DP, the first and second lens frames OS1 and OS2, and the first and second multi-channel lenses LS1 and LS2 may be assembled to and disposed (e.g., mounted) on the main frame MF. To this end, the main frame MF may include a space or structure in which the display panel DP, the first and second lens frames OS1 and OS2, and the first and second multi-channel lenses LS1 and LS2 may be accommodated. The main frame MF may further include a structure such as a strap or a band for easy mounting, and may further include a control unit, an image processing unit, a lens accommodating unit, or the like.

The display panel DP may be divided into a front surface DP_FS on which the image is displayed and a rear surface DP_RS disposed on a side opposite to the front surface DP_FS. The image display light may be emitted to the front surface DP_FS of the display panel DP. As described later, the first and second lens frames OS1 and OS2 may be disposed on the front surface DP_FS of the display panel DP, and the first and second multi-channel lenses LS1 and LS2 may be disposed on front surfaces of the first and second lens frames OS1 and OS2, respectively. Although not illustrated in FIG. 8, at least one infrared camera may be further disposed on at least one of the front surface DP_FS or the rear surface DP_RS of the display panel DP. The display panel DP may be substantially the same as the display panel 100 described with reference to FIG. 1 or the like.

The display panel DP may be embedded in the main frame MF or detachably assembled to the main frame MF, in a state in which the first and second lens frames OS1 and OS2 and the first and second multi-channel lenses LS1 and LS2 are disposed (e.g., mounted) thereon and fixed thereto. The display panel DP may be opaque, transparent, or translucent according to a design of the display device 10_1, e.g., a use form of the display device 10_1.

Each of the first and second lens frames OS1 and OS2 may have an area corresponding to an image display surface of the display panel DP and may be formed in a shape corresponding to the image display surface. In addition, the first and second lens frames OS1 and OS2 may be formed in areas and shapes corresponding to shapes of rear surfaces of the first and second multi-channel lenses LS1 and LS2, respectively. Rear surfaces of the first and second lens frames OS1 and OS2 may be attached to the image display surface of the display panel DP, and the first and second multi-channel lenses LS1 and LS2 may be attached to the front surfaces of the first and second lens frames OS1 and OS2, respectively. Such first and second lens frames OS1 and OS2 refract the image display light emitted from the image display surface of the display panel DP at a preset angle and provide the refracted image display light to the first and second multi-channel lenses LS1 and LS2 disposed on the front surfaces thereof, respectively.

Specifically, the first and second lens frames OS1 and OS2 may refract the image display light emitted in a front direction from the image display surface of the display panel DP in an outer direction (or an outer circumferential direction) as compared with the front direction and provide the refracted image display light to the first and second multi-channel lenses LS1 and LS2 disposed on the front surfaces thereof, respectively. In particular, the first and second lens frames OS1 and OS2 may refract the image display light incident on the rear surfaces thereof in the outer direction (or the outer circumferential direction) and provide the refracted image display light to the rear surfaces of the first and second multi-channel lenses LS1 and LS2, respectively.

The first and second multi-channel lenses LS1 and LS2 may form paths of the light emitted through the first and second lens frames OS1 and OS2 to allow the image display light to be visible to user's eyes in the front direction.

Each of the first and second multi-channel lenses LS1 and LS2 may provide a plurality of channels (or paths) through which the image display light emitted from the display panel DP passes. The plurality of channels may pass the image display light emitted from the display panel DP through different paths and provide the image display light to the user. The image display light emitted through the first and second lens frames OS1 and OS2 may be incident on the respective channels, and images magnified through the respective channels may be focused on the user's eyes.

The first and second multi-channel lenses LS1 and LS2 may be arranged on the front surfaces of the first and second lens frames OS1 and OS2 so as to correspond to positions of user's left and right eyes, respectively. The first and second multi-channel lenses LS1 and LS2 may be accommodated inside the main frame MF.

The first and second multi-channel lenses LS1 and LS2 may refract and/or reflect the image display light emitted through the first and second lens frames OS1 and OS2 at least once to define paths to the user's eyes. At least one infrared light source may be further disposed on one side of each of the first and second multi-channel lenses LS1 and LS2 facing the main frame MF or user's eyeballs.

The cover frame CVF may be disposed in a rear surface DP_RS direction of the display panel DP so as to cover the display panel DP, to protect the display panel DP. The cover frame CVF may cover the display panel DP and be disposed (e.g., mounted) on the main frame MF.

Although not illustrated in FIG. 8, the display device 10_1 may further include a control unit controlling an overall operation of the display device 10_1 including the display panel DP. The control unit may control an image display operation, an audio device, or the like, of the display panel DP. Specifically, the control unit performs image processing (e.g., image mapping) according to image display paths and a magnification according to the first and second lens frames OS1 and OS2 and the first and second multi-channel lenses LS1 and LS2, and controls the display panel DP to display the mapped image. The control unit may be implemented as a dedicated processor including an embedded processor or the like and/or a general-purpose processor including a central processing unit or an application processor, but is not limited thereto.

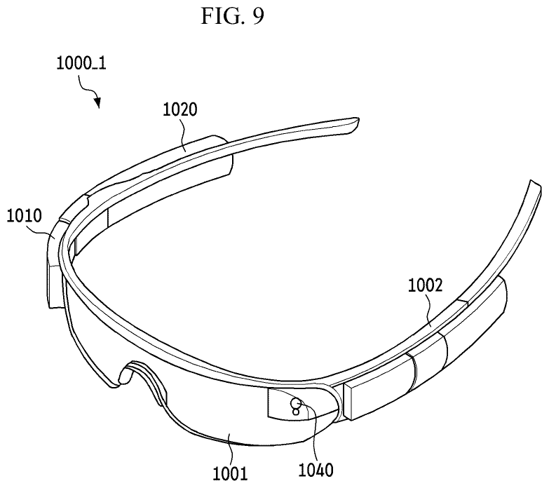

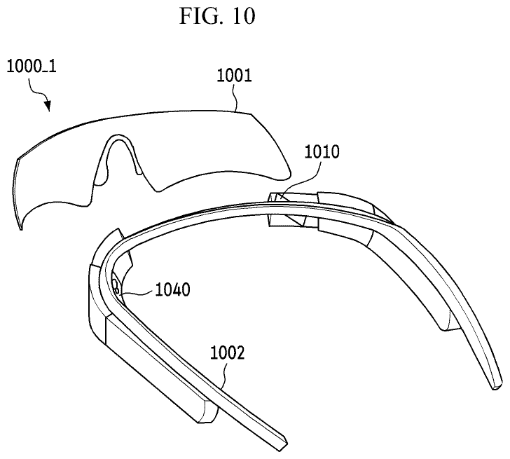

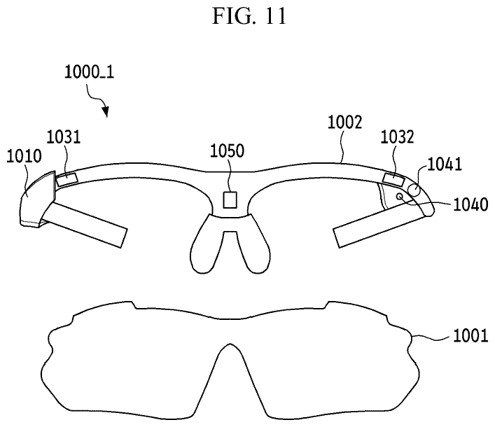

FIG. 9 is a perspective view illustrating an embodiment of an augmented reality content providing device. FIG. 10 is an exploded perspective view of the augmented reality content providing device of FIG. 9 viewed in a rear surface direction, and FIG. 11 is an exploded perspective view of the augmented reality content providing device of FIG. 10 viewed in a front surface direction.

Referring to FIGS. 9 to 11, an augmented reality content providing device 1000_1 may include a support frame 1002 supporting at least one transparent lens 1001, at least one image display module 1010, a surrounding environment detection unit 1040, and a control module 1020.

The support frame 1002 may be formed in the shape of glasses including a glasses frame supporting an edge of at least one transparent lens 1001 and glasses temples. A shape of the support frame 1002 is not limited to the shape of glasses, but may also be a goggle shape or a head mounted shape including a transparent lens 1001.

The transparent lens 1001 may be formed as an integral lens in left and right directions or configured as first and second transparent lenses separated from each other in the left and right directions. The transparent lens 1001 formed as the integral lens in the left and right directions or configured as the first and second transparent lenses separated from each other may include or consist of glass or plastic so as to be transparent or translucent. For this reason, a user may see a real image through the transparent lens 1001 formed as the integral lens in the left and right directions or configured as the first and second transparent lenses separated from each other. Here, the transparent lens 1001, that is, the integral lens or the first and second transparent lenses may have refractive power in consideration of a user's eyesight.

The transparent lens 1001 may further include at least one reflective member reflecting an augmented reality content image provided from at least one image display module 1010 toward the transparent lens 1001 or the user's eyes and optical members adjusting a focus and a size. At least one reflective member may be embedded in the transparent lens 1001 integrally with the transparent lens 1001, and may be formed as a plurality of refractive lenses or a plurality of prisms having a predetermined curvature.

At least one image display module 1010 may include a micro LED display device (“micro-LED”), a nano LED display device (“nano-LED”), an organic light-emitting display device (“OLED”), an inorganic light emitting display device, a quantum dot light-emitting display device (“QED”), a cathode ray display (“CRT”), a liquid crystal display (“LCD”), or the like. The image display module 1010 may substantially include the display device 10 described with reference to FIG. 1 or the like.

The surrounding environment detection unit 1040 is assembled to or formed integrally with the support frame 1002 and detects a distance (or a depth) to an object of a front surface direction of the support frame 1002, illuminance, a moving direction, a moving distance, and a tilt of the support frame 1002, or the like. To this end, the surrounding environment detection unit 1040 includes a depth sensor 1041 such as an infrared sensor or a light detection and ranging (“LiDAR”) sensor, and an image sensor 1050 such as a camera. In addition, the surrounding environment detection unit 1040 may further include at least one motion sensor of an illuminance sensor, a human body detection sensor, a gyro sensor, a tilt sensor, and an acceleration sensor. Further, the surrounding environment detection unit 1040 may further include first and second biometric sensors 1031 and 1032 detecting movement information of user's eyeballs or pupils.

The surrounding environment detection unit 1040 may transmit sensing signals generated through the depth sensor 1041, at least one motion sensor, or the like, to the control module 1020 in real time. In addition, the image sensor 1050 may transmit image data in at least one frame unit generated in real time to the control module 1020. The first and second biometric sensors 1031 and 1032 of the surrounding environment detection unit 1040 may transmit pupil sensing signals respectively detected by the first and second biometric sensors 1031 and 1032 to the control module 1020.

The control module 1020 may be assembled to at least one side of the support frame 1002 together with at least one image display module 1010 or formed integrally with the support frame 1002. The control module 1020 supplies augmented reality content data to at least one image display module 1010 so that the at least one image display module 1010 displays an augmented reality content such as an augmented reality content image. At the same time, the control module 1020 may receive the sensing signals, the image data, and the pupil detection signals from the surrounding environment detection unit 1040 in real time.

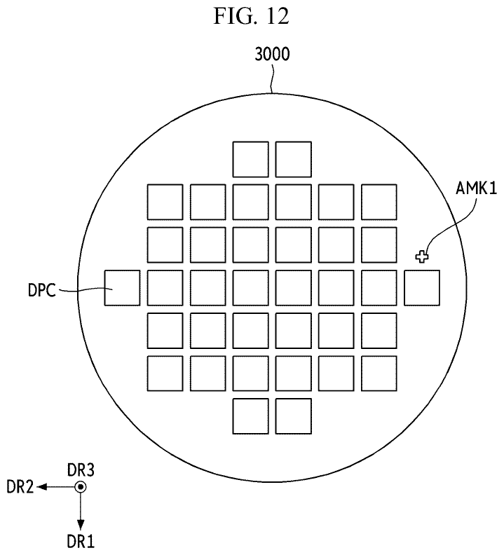

FIG. 12 is a plan view illustrating an embodiment of a mother semiconductor substrate including a display cell.

Referring to FIG. 12 in addition to FIGS. 1 to 11, a mother semiconductor substrate 3000 may be configured as a semiconductor wafer. The mother semiconductor substrate 3000 may include a group IV material or a group III-V compound. In some embodiments, the mother semiconductor substrate 3000 may be configured as a single crystal wafer. In an embodiment, the mother semiconductor substrate 3000 may be a silicon substrate, a germanium substrate, or a silicon-germanium substrate, for example.

However, the mother semiconductor substrate 3000 is not limited to the single crystal wafer, and may be various wafers such as an epi or epitaxial wafer, a polished wafer, an annealed wafer, and a silicon on insulator (“SOI”) wafer. The epitaxial wafer refers to a wafer in which a crystalline material is grown on a single crystal silicon substrate.

The mother semiconductor substrate 3000 may include a first alignment mark AMK1. The first alignment mark AMK1 will be described later.

The mother semiconductor substrate 3000 may include a plurality of display cells DPC. The plurality of display cells DPC may be preprocessing components that constitute a portion of the display panel 100 described above. In an embodiment, the mother semiconductor substrate 3000 may constitute the semiconductor substrate SSUB of the display panel 100, and the plurality of display cells DPC may constitute the semiconductor backplane SBP, the display element layer EML, and the encapsulation layer TFE of the display panel 100, for example.

The plurality of display cells DPC may be formed using semiconductor equipment or formed by a semiconductor process, but are not limited thereto. The display panel 100 may be formed by forming the plurality of display cells DPC on the mother semiconductor substrate 3000 and then performing cell cutting in units of each display cell DPC.

Although not illustrated in FIG. 12, each of the plurality of display cells DPC may include a plurality of pixels PX, and each of the plurality of pixels PX may include a plurality of light-emitting elements. The light-emitting layer IL included in the light-emitting element may be formed through a deposition process. In general, in order to form the light-emitting layer IL in a high-resolution display device 10 through the deposition process, a more precise deposition mask may be desired. Hereinafter, a deposition mask for forming the high-resolution display device 10 will be described.

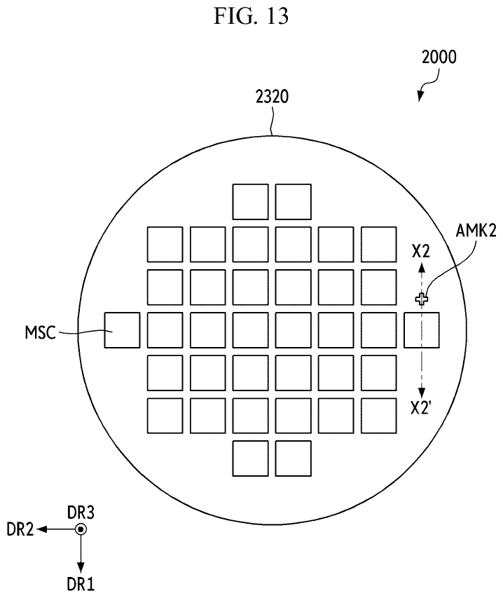

FIG. 13 is a plan view illustrating an embodiment of a deposition mask including a mask cell.

Referring to FIG. 13 in addition to FIGS. 1 to 12, a deposition mask 2000 in an embodiment may be a deposition mask used to manufacture an ultrahigh-resolution display. In an embodiment, the deposition mask 2000 may be a deposition mask used to manufacture a display included in a head mounted display device or an augmented reality content providing device.

In an embodiment, the deposition mask 2000 may be used to perform a pixel deposition process on a silicon wafer. In general, a display included in an extended reality device may have a relatively small screen rather than a size of a great area because a screen is disposed directly in front of user's eyes. In addition, such a display may desire an ultrahigh-resolution because the screen is disposed close to the user's eyes. In an embodiment, a resolution desired in the display included in the extended reality device may be approximately 1000 pixels per inch (PPI) or higher, and preferably, an ultrahigh resolution of 3000 PPI or higher. The deposition mask 2000 in an embodiment may be a mask used to manufacture such an ultrahigh-resolution display. In other words, the deposition mask 2000 may be a fine silicon mask (“FSM”).

The deposition mask 2000 may include a mask substrate 2320 and a plurality of mask cells MSC. The mask substrate 2320 may be disposed to surround each mask cell MSC.

The mask substrate 2320 may be configured as a semiconductor wafer. The mask substrate 2320 may include a group IV material or a group III-V compound. In some embodiments, the mask substrate 2320 may be configured as a single crystal wafer. In an embodiment, the mask substrate 2320 may be a silicon substrate, a germanium substrate, or a silicon-germanium substrate, for example. However, the mask substrate 2320 is not limited to the single crystal wafer, and may be various wafers such as an epi or epitaxial wafer, a polished wafer, an annealed wafer, and a silicon on insulator (SOI) wafer. The epitaxial wafer refers to a wafer in which a crystalline material is grown on a single crystal silicon substrate.

The mask substrate 2320 is a substrate of the ultrahigh-resolution display, and may have the same size or shape as the mother semiconductor substrate 3000.

The plurality of mask cells MSC may be disposed to correspond to the plurality of display cells DPC of the mother semiconductor substrate 3000. In an embodiment, in a deposition process for manufacturing the display device 10, a plurality of mask cells MSC may overlap the plurality of display cells DPC of the mother semiconductor substrate 3000, respectively, for example.

In this case, in order to align the plurality of mask cells MSC so as to overlap the plurality of display cells DPC, the mother semiconductor substrate 3000 may include the first alignment mark AMK1, and the deposition mask 2000 may include a second alignment mark AMK2. The first alignment mark AMK1 and the second alignment mark AMK2 may each include metal, but are not limited thereto.

The plurality of mask cells MSC may be formed using semiconductor equipment or formed by a semiconductor process, but are not limited thereto. The deposition mask 2000 in the illustrated embodiment may include an ultrahigh-resolution pattern by forming the plurality of mask cells MSC on the mask substrate 2320 configured as the semiconductor wafer using the semiconductor equipment or through the semiconductor process. The ultrahigh-resolution display may be manufactured using such an ultrahigh-resolution pattern.

The features of the deposition mask 2000 described above may be substantially the same as features of deposition masks 2000p, 2000q, and 2000r to be described below.

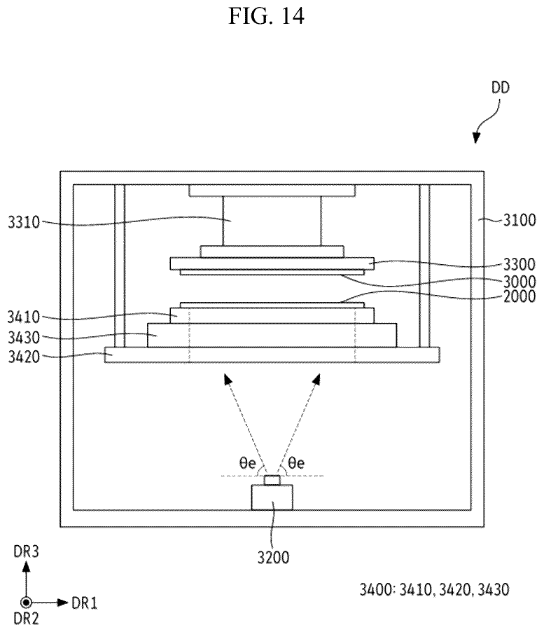

FIG. 14 is a schematic view for describing an embodiment of a deposition device of manufacturing a display panel using the deposition mask.

Referring to FIG. 14 in addition to FIGS. 1 to 13, a deposition device DD may be used to form light-emitting material layers on the mother semiconductor substrate 3000 in a manufacturing process of the display panel 100. In other words, the deposition device DD may be used to form the light-emitting layer IL illustrated in FIG. 7.

The deposition device DD may include a process chamber 3100. The process chamber 3100 may include an internal space, and a deposition process for forming a deposition material layer on the mother semiconductor substrate 3000 may be performed in the internal space of the process chamber 3100. Although not illustrated, the process chamber 3100 may be connected to a vacuum pump (not illustrated), and a vacuum atmosphere may be created in the internal space of the process chamber 3100 by the vacuum pump. An opening (not illustrated) for the entrance and exit of the mother semiconductor substrate 3000 and the deposition mask 2000 may be provided in one sidewall of the process chamber 3100, and may be opened and closed by a gate valve (not illustrated).

The deposition mask 2000 and the mother semiconductor substrate 3000 may be disposed to face each other. In an embodiment, the deposition mask 2000 may be disposed toward one side of the third direction DR3, and the mother semiconductor substrate 3000 may be disposed toward an opposite side of the third direction DR3. The mother semiconductor substrate 3000 may be supported by a substrate chuck 3300. That is, the substrate chuck 3300 may support the mother semiconductor substrate 3000 so that a front surface of the mother semiconductor substrate 3000 faces downward, and may position the mother semiconductor substrate 3000 on the deposition mask 2000 in order to perform the deposition process.

An upper driver 3310 moving and rotating the substrate chuck 3300 may be disposed above the substrate chuck 3300 in order to adjust a position and an angle of the mother semiconductor substrate 3000. In an embodiment, the upper driver 3310 may move the substrate chuck 3300 in the first direction DR1 and the second direction DR2 in order to adjust a horizontal position of the mother semiconductor substrate 3000, and may move the substrate chuck 3300 in the third direction DR3 in order to adjust a vertical position of the mother semiconductor substrate 3000, for example. In this case, the first direction DR1, the second direction DR2, and the third direction DR3 may be an X-axis direction, a Y-axis direction, and a Z-axis direction, respectively.

The deposition mask 2000 may be disposed on a mask stage 3400. The mask stage 3400 may include a mask chuck 3410 for supporting the deposition mask 2000, a support plate 3420, and a lower driver 3430.

The mask chuck 3410 may have a circular ring shape so as to support an edge portion of the deposition mask 2000. In an embodiment, the mask chuck 3410 may be an electrostatic chuck gripping the edge portion of the deposition mask 2000 using electrostatic force, for example.

The support plate 3420 may define an opening so that the deposition mask 2000 is exposed toward a deposition source 3200, and the lower driver 3430 for adjust a position and an angle of the deposition mask 2000 may be disposed between the support plate 3420 and the mask chuck 3410. In an embodiment, the lower driver 3430 may move the mask chuck 3410 in the first direction DR1 and the second direction DR2 in order to adjust a horizontal position of the deposition mask 2000, and may rotate the mask chuck 3410 around a Z axis in order to adjust an azimuth angle of the deposition mask 2000.

The deposition source 3200 may be disposed on an opposite side of the third direction DR3. The deposition source 3200 may be disposed below the deposition mask 2000 The deposition source 3200 may spray a deposition material in a range of a deposition incident angle θe, and the sprayed deposition material may be seated on the mother semiconductor substrate 3000 through the deposition mask 2000. In an embodiment, the deposition incident angle θe may be 85° or more and less than 95°.

The deposition mask 2000 in an embodiment may effectively deposit the light-emitting layer IL without a separate cell margin area on at least one of the deposition mask 2000 or the mother semiconductor substrate 3000 because the mask substrate 2320 includes a tapered angle smaller than the deposition incident angle θe. In an embodiment, when the mask substrate 2320 includes a tapered angle (e.g., 90°) greater than the deposition incident angle θe, the deposition material sprayed from the deposition source 3200 may be blocked by the mask substrate 2320, such that material loss may be caused, and for this reason, it is desired to design a light-emitting layer IL deposition target area at a greater width. Accordingly, the deposition mask 2000 in an embodiment may have manufacturing easiness. A detailed description will be provided later.

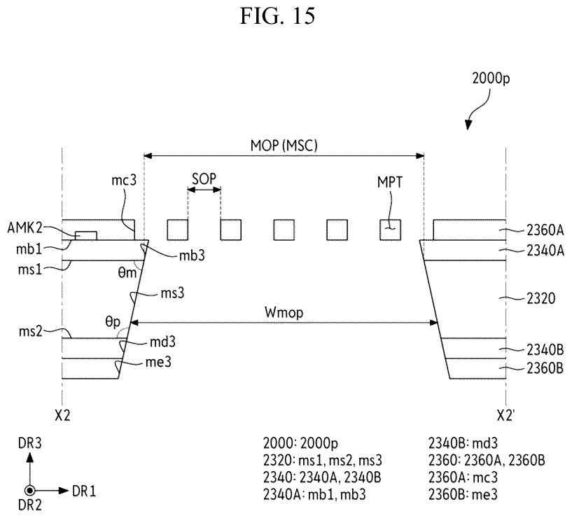

FIG. 15 is a cross-sectional view taken along line X2-X2′ of FIG. 13.

Referring to FIG. 15 in addition to FIGS. 1 to 14, a deposition mask 2000p in an embodiment may include a mask substrate 2320, an auxiliary coating film 2340, a second alignment mark AMK2, a main coating film 2360, and a mask pattern MPT. The auxiliary coating film 2340 may include an upper auxiliary coating film 2340A and a lower auxiliary coating film 2340B, and the main coating film 2360 may include an upper main coating film 2360A and a lower main coating film 2360B.

The mask substrate 2320 may define a mask opening MOP, and may be disposed to surround the mask opening MOP. A plurality of mask openings MOP may correspond to the mask cells MSC. In an embodiment, the plurality of mask openings MOP may be disposed in the plurality of multiple mask cells MSC, respectively, for example. However, the disclosure is not limited thereto, and one mask opening MOP may be defined over the entirety of the plurality of mask cells MSC.

The mask substrate 2320 may include a first surface ms1, a second surface ms2, and a side surface ms3. The first surface ms1 of the mask substrate 2320 may be one surface facing the main coating film 2360, the second surface ms2 of the mask substrate 2320 may be one surface opposing the first surface ms1, and the side surface ms3 of the mask substrate 2320 may be a surface facing the mask opening MOP. The side surface ms3 may be one surface extending to the first surface ms1 and the second surface ms2.

The side surface ms3 of the mask substrate 2320 may be an inclined surface inclined between the first direction DR1 and the third direction DR3. A first inclination angle θm defined by the side surface ms3 and the first surface ms1 of the mask substrate 2320 may be an acute angle, and a second inclination angle θp defined by the side surface ms3 and the second surface ms2 of the mask substrate 2320 may be an obtuse angle. In an embodiment, the first inclination angle θm defined by the side surface ms3 and the first surface ms1 of the mask substrate 2320 may have a range of 53° or more and 55° or less. The first inclination angle θm and the second inclination angle θp may be defined by removing a portion of the mask substrate 2320 by a wet etching process in a manufacturing process of the deposition mask 2000p. The manufacturing process will be described later.

As described above, when the first inclination angle θm has a value out of the above-described range, the deposition material sprayed from the deposition source 3200 in FIG. 14 may be blocked by the mask substrate 2320, such that the material loss may be caused, and for this reason, it is desired to design the light-emitting layer IL deposition target area at a greater width. In other words, at least one of the deposition mask 2000 or the mother semiconductor substrate 3000 may desire a separate margin area, and accordingly, it may be difficult to implement an ultrahigh-resolution product.

The auxiliary coating film 2340 may be disposed on the mask substrate 2320. The auxiliary coating film 2340 may contact the mask substrate 2320. The auxiliary coating film 2340 may be disposed to surround the mask opening MOP.

The auxiliary coating film 2340 may include an inorganic insulating material, and may include silicon oxide (SiOₓ) having compressive stress physical properties, for example.

The auxiliary coating film 2340 may include the upper auxiliary coating film 2340A disposed on the first surface ms1 of the mask substrate 2320 and the lower auxiliary coating film 2340B disposed on the second surface ms2 of the mask substrate 2320. In the manufacturing process of the deposition mask 2000p, the upper auxiliary coating film 2340A and the lower auxiliary coating film 2340B may be formed simultaneously in the same process. However, in an embodiment, the lower auxiliary coating film 2340B may be omitted.

In some embodiments, the upper auxiliary coating film 2340A may include a first surface mb1 and a side surface mb3. The first surface mb1 may be one surface facing the upper main coating film 2360A, and the side surface mb3 may be one surface facing the mask opening MOP.

In some embodiments, the side surface mb3 of the upper auxiliary coating film 2340A and a side surface md3 of the lower auxiliary coating film 2340B may be disposed on the same line as the side surface ms3 of the mask substrate 2320, but are not limited thereto. The above-described same line may have the same meaning as “disposed to be aligned”, “connected”, or “extending”.

The second alignment mark AMK2 may be disposed on the upper auxiliary coating film 2340A. However, the disclosure is not limited thereto, and a position of the second alignment mark AMK2 may be changed.

The main coating film 2360 may be disposed on the second alignment mark AMK2 and the auxiliary coating film 2340. The main coating film 2360 may be disposed to surround the mask opening MOP.

The main coating film 2360 may include an inorganic insulating material, and may include silicon nitride (SiNₓ) having tensile stress physical properties, for example.

In the deposition mask 2000p in an embodiment, the auxiliary coating film 2340 and the main coating film 2360 may be formed to have different stress physical properties, such that the main coating film 2360 and the auxiliary coating film 2340 may have thin film stress in a neural state. Accordingly, the deposition mask 2000p may solve a reliability defect such as a film peeling defect or a cell burst defect caused in the manufacturing process.

The main coating film 2360 may include the upper main coating film 2360A disposed on the first surface ms1 of the mask substrate 2320 and in contact with the upper auxiliary coating film 2340A and the lower main coating film 2360B disposed on the second surface ms2 of the mask substrate 2320 and in contact with the lower auxiliary coating film 2340B. In the manufacturing process of the deposition mask 2000p, the upper main coating film 2360A and the lower main coating film 2360B may be formed simultaneously in the same process.

However, in an embodiment, the lower main coating film 2360B may be omitted.

In some embodiments, a side surface mc3 of the upper main coating film 2360A may be depressed more than the side surface ms3 of the mask substrate 2320 and the side surface mb3 of the upper auxiliary coating film 2340A in a direction opposite to a direction toward the mask opening MOP. Accordingly, a portion of the first surface mb1 of the upper auxiliary coating film 2340A may be exposed without being covered by the upper main coating film 2360A. In other words, the upper main coating film 2360A may be in entire contact with the upper auxiliary coating film 2340A, and accordingly, adhesion characteristics of the upper main coating film 2360A may be improved.

In some embodiments, a side surface me3 of the lower main coating film 2360B may be disposed on the same line as the side surface ms3 of the mask substrate 2320 and the side surface md3 of the lower auxiliary coating film 2340, but is not limited thereto.

In an embodiment, a width Wmop of the mask opening MOP in the first direction DR1 may become smaller toward one side of the third direction DR3. In other words, the width Wmop of the mask opening MOP may become smaller toward the upper auxiliary coating film 2340A and may become greater toward the lower auxiliary coating film 2340B. This may be caused because the side surface ms3 of the mask substrate 2320 is formed as an inclined surface that is constantly inclined.

In other words, the width Wmop of the mask opening MOP overlapping the upper auxiliary coating film 2340A may be smaller than the width Wmop of the mask opening MOP overlapping the mask substrate 2320, and the width Wmop of the mask opening MOP overlapping the lower auxiliary coating film 2340B may be greater than the width Wmop of the mask opening MOP overlapping the mask substrate 2320.

The deposition mask 2000p in an embodiment may include a plurality of mask patterns MPT in a portion that overlaps the mask opening MOP. The plurality of mask patterns MPT may not overlap the mask substrate 2320 in the third direction DR3.

The respective mask patterns MPT may be spaced apart from each other with a pixel opening SOP interposed therebetween, and some mask patterns MPT may be spaced apart from the main coating film 2360 with a pixel opening SOP interposed therebetween.

The plurality of mask patterns MPT may be spaced apart from each other in the first direction DR1 or the second direction DR2 in cross section, but may be one pattern connected to each other in a plan view. In other words, the mask pattern MPT may refer to all of a plurality of patterns disposed on the mask substrate 2320 as one configuration or may refer to each of the plurality of patterns. That is, the plurality of mask patterns MPT may be used interchangeably to refer to the entirety of a group of the plurality of patterns as one configuration or refer to each of the plurality of patterns.

The mask pattern MPT may include the same material as that of the main coating film 2360. In the manufacturing process of the deposition mask 2000p, the mask pattern MPT and the main coating film 2360 are formed integrally with each other, and portions of the main coating film 2360 are then removed by a subsequent etching process, and accordingly, the mask pattern MPT and the main coating film 2360 may be divided into forms of the mask pattern MPT and the main coating film 2360 illustrated in FIG. 15.

In some embodiments, the mask pattern MPT may have a reverse tapered shape, but is not limited thereto.

The pixel opening SOP in an embodiment may be in communication with the mask opening MOP. Accordingly, the mask opening MOP and the pixel opening SOP may provide a passage through which a deposition material for forming the pixel PX of the display panel 100 included in the display device 10 may move.

In the deposition mask 2000p, the mask substrate 2320 includes the side surface ms3 that is inclined, and accordingly, a material for forming the light-emitting layer IL may be deposited on the mother semiconductor substrate 3000 through the mask opening MOP and the pixel opening SOP without a separate cell margin area. The fact that the first inclination angle θm of the mask substrate 2320 has the range of 53° or more and 55° or less may have important significance in the above-described effect.

In addition, in the deposition mask 2000p, the upper main coating film 2360A is formed in entire contact with the first surface ms1 of the mask substrate 2320, such that the adhesion characteristics of the upper main coating film 2360A may be improved.

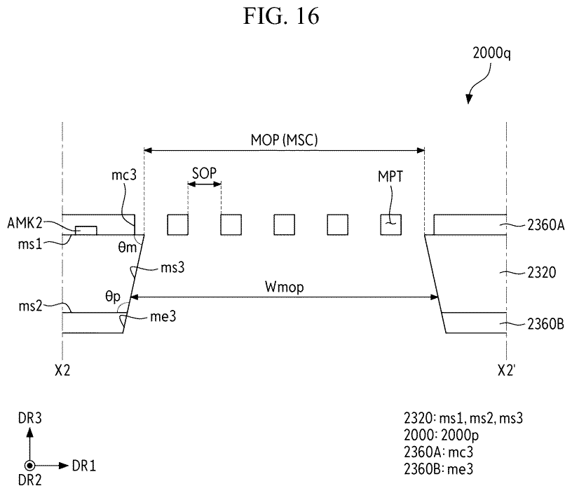

FIG. 16 is a cross-sectional view taken along line X2-X2′ of another embodiment of FIG. 13.

Referring to FIG. 16 in addition to FIGS. 1 to 15, a deposition mask 2000q may include a pixel opening SOP and a mask pattern MPT in a portion that overlaps a mask opening MOP, and may include a mask substrate 2320, a second alignment mark AMK2, and a main coating film 2360 that are sequentially stacked in a portion that does not overlap the mask opening MOP. The deposition mask 2000q is different from the deposition mask 2000q described above in that it does not include the auxiliary coating film 2340 of the deposition mask 2000q.

Hereinafter, the same components as those of the deposition mask 2000p according to the above-described embodiment will be denoted by the same reference numerals, and an overlapping description thereof will be omitted or simplified and contents different from those described above will be mainly described.

The mask substrate 2320 of the deposition mask 2000q may define the mask opening MOP, and may be disposed to surround the mask opening MOP.

A first inclination angle θm defined by a side surface ms3 and a first surface ms1 included in the mask substrate 2320 of the deposition mask 2000q may be an acute angle, and a second inclination angle θp defined by the side surface ms3 and a second surface ms2 included in the mask substrate 2320 may be an obtuse angle. In an embodiment, the first inclination angle θm may have a range of 53° or more and 55° or less. The first inclination angle θm and the second inclination angle θp may be defined by removing a portion of the mask substrate 2320 by a wet etching process in a manufacturing process of the deposition mask 2000q.

A width Wmop of the mask opening MOP in the first direction DR1 may become smaller toward one side of the third direction DR3. In other words, the width Wmop of the mask opening MOP may become smaller toward an upper main coating film 2360A and may become greater toward a lower main coating film 2360B. This may be caused because the side surface ms3 of the mask substrate 2320 is formed as an inclined surface that is constantly inclined.

The second alignment mark AMK2 may be disposed on the mask substrate 2320. However, the disclosure is not limited thereto, and a position of the second alignment mark AMK2 may be changed.

The main coating film 2360 may be disposed on the second alignment mark AMK2 and the mask substrate 2320. The main coating film 2360 may be disposed to surround the mask opening MOP.

The main coating film 2360 may include an inorganic insulating material, and may include silicon nitride (SiNₓ) having tensile stress physical properties, for example.

The main coating film 2360 may include the upper main coating film 2360A disposed to contact the first surface ms1 of the mask substrate 2320 and the lower main coating film 2360B disposed to contact the second surface ms2 of the mask substrate 2320. In an embodiment, the lower main coating film 2360B may be omitted.

In some embodiments, a side surface mc3 of the upper main coating film 2360A may be depressed more than the side surface ms3 of the mask substrate 2320 in a direction opposite to a direction toward the mask opening MOP. An overlapping description is omitted.

In some embodiments, a side surface me3 of the lower main coating film 2360B may be disposed on the same line as the side surface ms3 of the mask substrate 2320, but is not limited thereto.

The deposition mask 2000q in an embodiment may include a plurality of mask patterns MPT and pixel openings SOP in the portion that overlaps the mask opening MOP. An overlapping description is omitted.

In the deposition mask 2000q, the mask substrate 2320 includes the side surface ms3 that is constantly inclined, and accordingly, a material for forming the light-emitting layer IL may be deposited on the mother semiconductor substrate 3000 through the mask opening MOP and the pixel opening SOP without a separate cell margin area. The fact that the first inclination angle θm of the mask substrate 2320 has the range of 53° or more and 55° or less may have important significance in the above-described effect.

In addition, in the deposition mask 2000q, the upper main coating film 2360A is formed in entire contact with the first surface ms1 of the mask substrate 2320, such that adhesion characteristics of the upper main coating film 2360A may be improved.

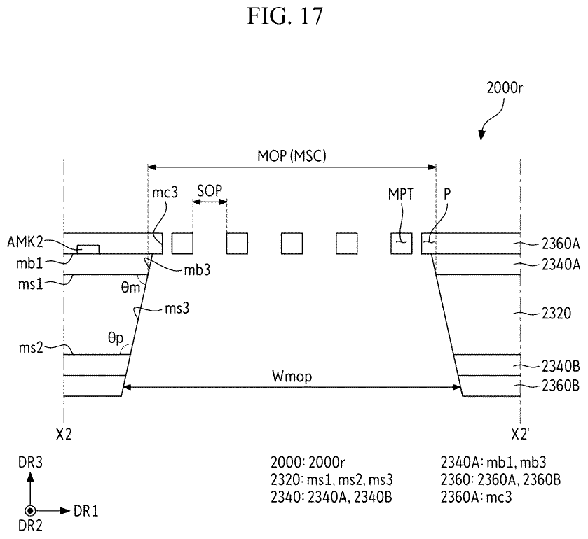

FIG. 17 is a cross-sectional view taken along line X2-X2′ of another embodiment of FIG. 13.

Referring to FIG. 17 in addition to FIGS. 1 to 16, a deposition mask 2000r may include a pixel opening SOP and a mask pattern MPT in a portion that overlaps a mask opening MOP, and may include a mask substrate 2320, a second alignment mark AMK2, an auxiliary coating film 2340, and a main coating film 2360 that are sequentially stacked in a portion that does not overlap the mask opening MOP. The auxiliary coating film 2340 may include an upper auxiliary coating film 2340A and a lower auxiliary coating film 2340B, and the main coating film 2360 may include an upper main coating film 2360A and a lower main coating film 2360B. In an embodiment, the lower auxiliary coating film 2340B and the lower main coating film 2360B may be omitted.

The deposition mask 2000r is different from the deposition mask 2000p in that the upper main coating film 2360A thereof has a different shape from the upper main coating film 2360A of the deposition mask 2000p.

Hereinafter, the same components as those of the deposition mask 2000p according to the above-described embodiment will be denoted by the same reference numerals, and an overlapping description thereof will be omitted or simplified and contents different from those described above will be mainly described.

The mask substrate 2320 of the deposition mask 2000r may define the mask opening MOP, and may be disposed to surround the mask opening MOP.

A first inclination angle θm defined by a side surface ms3 and a first surface ms1 included in the mask substrate 2320 of the deposition mask 2000r may be an acute angle, and a second inclination angle θp defined by the side surface ms3 and a second surface ms2 included in the mask substrate 2320 may be an obtuse angle. In an embodiment, the first inclination angle θm may have a range of 53° or more and 55° or less.

A width Wmop of the mask opening MOP in the first direction DR1 may become smaller toward one side of the third direction DR3. An overlapping description is omitted.

The main coating film 2360 of the deposition mask 2000r may be disposed on the second alignment mark AMK2 and the auxiliary coating film 2340. The main coating film 2360 may be disposed to surround the mask opening MOP.

A side surface mc3 of the upper main coating film 2360A of the deposition mask 2000r may protrude more than the side surface ms3 of the mask substrate 2320 and a side surface mb3 of the upper auxiliary coating film 2340A in a direction toward the mask opening MOP. Accordingly, the upper main coating film 2360A may have a protrusion portion P protruding toward the mask opening MOP.

A first surface mb1 of the upper auxiliary coating film 2340A of the deposition mask 2000r may be entirely covered by the upper main coating film 2360A.

The protrusion portion P of the upper main coating film 2360A may be spaced apart from the mask pattern MPT with the pixel opening SOP interposed therebetween. It has been illustrated in FIG. 17 that a width of the pixel opening SOP defined between the protrusion portion P of the upper main coating film 2360A and the mask pattern MPT is smaller than a width defined between a plurality of pixel openings SOP, but the disclosure is not limited thereto.

In the deposition mask 2000r, the mask substrate 2320 includes the side surface ms3 that is constantly inclined, and accordingly, a material for forming the light-emitting layer IL may be deposited on the mother semiconductor substrate 3000 through the mask opening MOP and the pixel opening SOP without a separate cell margin area. The fact that the first inclination angle θm of the mask substrate 2320 has the range of 53° or more and 55° or less may have important significance in the above-described effect.

Hereinafter, a method of manufacturing the deposition mask 2000 will be described.

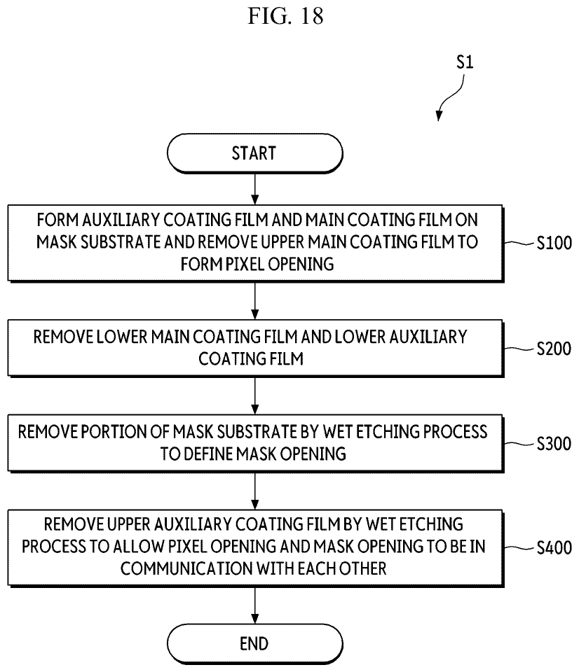

FIG. 18 is a flowchart illustrating an embodiment of a method of manufacturing the deposition mask.

Referring to FIG. 18, a method of manufacturing the deposition mask in an embodiment (S1) may include forming an auxiliary coating film and a main coating film on a mask substrate and removing an upper main coating film to define a pixel opening (S100), removing a lower main coating film and a lower auxiliary coating film (S200), removing a portion of the mask substrate by a wet etching process to define a mask opening (S300), and removing an upper auxiliary coating film by a wet etching process to allow the pixel opening and the mask opening to be in communication with each other (S400).

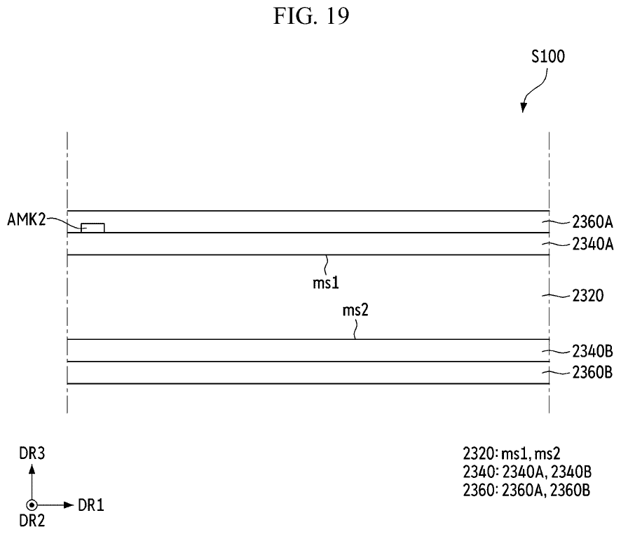

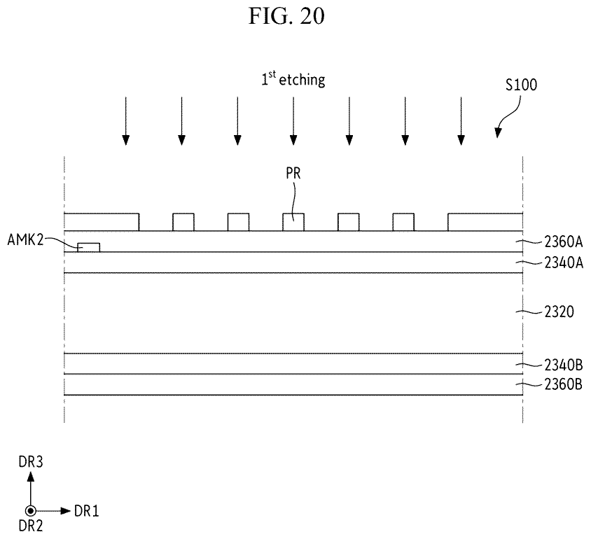

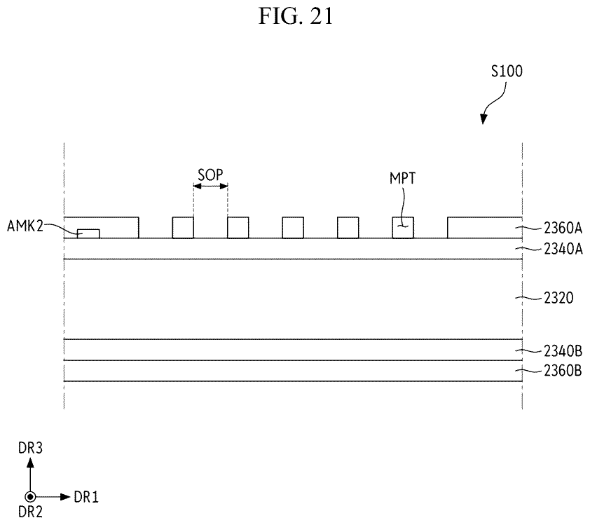

FIGS. 19 to 21 are cross-sectional views illustrating S100 of FIG. 18.

First, the forming of the auxiliary coating film and the main coating film on the mask substrate and the removing of the upper main coating film to define the pixel opening (S100) is described.

Referring to FIGS. 19 to 21, an auxiliary coating film 2340 is formed on a mask substrate 2320. The auxiliary coating film 2340 may include an upper auxiliary coating film 2340A formed on a first surface ms1 of the mask substrate 2320 and a lower auxiliary coating film 2340B formed on a second surface ms2 of the mask substrate 2320. In addition, the auxiliary coating film 2340 may also be formed on an edge surface (not illustrated) of the mask substrate 2320.

In the process, the auxiliary coating film 2340 may be formed through a wet thermal oxidation (“WTO”) process. The WTO process refers to a process of forming an oxide film by oxidizing the first surface ms1 and the second surface ms2 of the mask substrate 2320 at a relatively high temperature in an atmosphere including water vapor. The process may form a high-quality oxide film, and in this process, silicon is consumed, such that an oxide film may be formed in a ratio of 55% on the first surface ms1 of the mask substrate 2320 and in a ratio of 45% beneath the second surface ms2 of the mask substrate 2320. In an embodiment, the auxiliary coating film 2340 may be formed at a thickness of about 0.5 micrometer (μm) to about 2 μm on the mask substrate 2320.

In the process, the auxiliary coating film 2340 may be formed by putting the mask substrate 2320 into a slit, and accordingly, the upper auxiliary coating film 2340A and the lower auxiliary coating film 2340B may be formed simultaneously in the same process. However, in an embodiment, the auxiliary coating film 2340 may include only the upper auxiliary coating film 2340A.

A second alignment mark AMK2 may be formed by a process of patterning metal, and a position of the second alignment mark AMK2 may be changed. A description of overlapping contents is omitted.

Subsequently, a main coating film 2360 is formed on the auxiliary coating film 2340. The main coating film 2360 may include an upper main coating film 2360A formed on the first surface ms1 of the mask substrate 2320 and a lower main coating film 2360B formed on the second surface ms2 of the mask substrate 2320. In addition, the main coating film 2360 may also be formed on the edge surface (not illustrated) of the mask substrate 2320.

In the process, the main coating film 2360 may include silicon nitride (SiNₓ), and may be formed through a low pressure chemical vapor deposition (“LPCVD”) process. Specifically, the main coating film 2360 may be formed by supplying a first source gas including silicon and a second source gas including nitrogen into a chamber and then reacting the first source gas and the second source gas with each other. In an embodiment, a dichlorosilane (“DCS”) (SiH₂Cl₂) gas may be used as the first source gas, and an ammonia (NH₃) gas may be used as the second source gas. In an embodiment, the main coating film 2360 may be formed at a thickness of about 0.5 μm to about 3 μm on the mask substrate 2320.

In the process, the main coating film 2360 may be formed by putting the mask substrate 2360 into the slit, and accordingly, the upper main coating film 2360A and the lower main coating film 2360B may be formed simultaneously in the same process. However, in an embodiment, the main coating film 2360 may include only the upper main coating film 2360A.

Subsequently, a plurality of photoresists PR are formed on the upper main coating film 2360A. In the process, the plurality of photoresists PR may be spaced apart from each other.

Thereafter, a first etching process (1^{st} etching) is performed using the plurality of photoresists PR as a mask. In an embodiment, a dry etching process may be performed as the first etching process (1^{st} etching), and in an embodiment, a reactive ion etching (“RIE”) process using a reaction gas such as CHF₃, CH₃F, CH₂F₂, CHF₆, CF₄, C₂F₆, or C₃F₆, and a sputtering gas such as Ar or O₂/Ar may be performed. In this case, an inductively coupled plasma (“ICP”) source or a capacitively coupled plasma (“CCP”) source may be used as a plasma source.

In the process, portions of the upper main coating film 2360A may be removed by a predetermined width by appropriately controlling flow rates of the reaction gas and the sputtering gas, an internal temperature of a process chamber, radio frequency (“RF”) power for forming plasma, bias power applied to a chuck on which the mask substrate 2320 is put, or the like.

In the process, the upper main coating film 2360A that does not overlap the plurality of photoresists PR may be removed, and for this reason, a pixel opening SOP and a mask pattern MPT may be formed. In the process, the upper auxiliary coating film 2340A may be exposed at a portion that overlaps the pixel opening SOP. In other words, the mask pattern MPT may be integral with the upper main coating film 2360A and be then separated from the upper main coating film 2360A with the pixel opening SOP interposed therebetween by the first etching process (1^{st} etching) described above.

In the process, the plurality of photoresists PR may be removed through a stripping and/or ashing process.

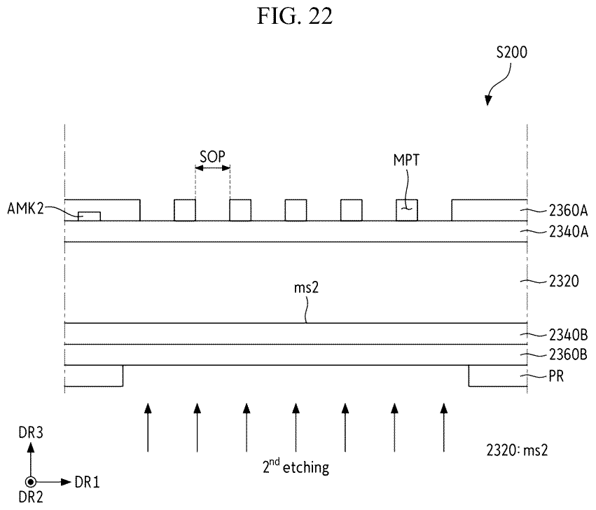

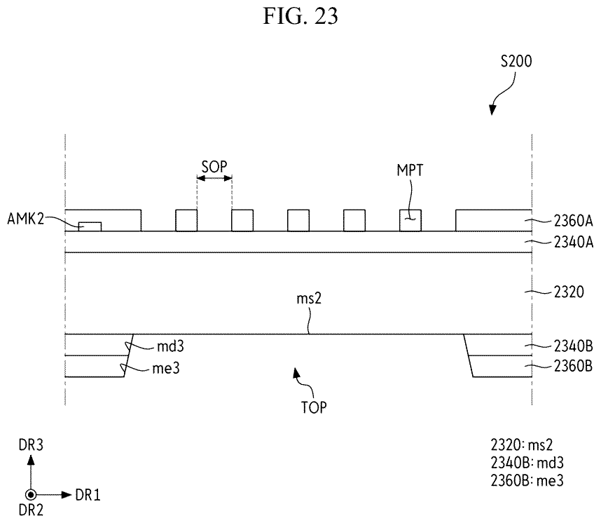

FIGS. 22 and 23 are cross-sectional views illustrating S200 of FIG. 18.

Second, the removing of the lower main coating film and the lower auxiliary coating film (S200) is described.

Referring to FIGS. 22 and 23, a photoresist PR is formed on the lower main coating film 2360B in a direction of the second surface ms2 of the mask substrate 2320, and a second etching process (2^{nd} etching) is performed.

In the process, a plurality of photoresists PR may not overlap the mask pattern MPT, and the second etching process (2^{nd} etching) may be performed toward the second surface ms2 of the mask substrate 2320. That is, the second etching process (2^{nd} etching) may be performed in a rear surface direction of the mask substrate 2320.

In an embodiment, in the second etching process (2^{nd} etching), a wet etching process and a dry etching process may be alternately performed.

First, the lower main coating film 2360B may be removed by performing the dry etching process. In the process, a portion of the lower main coating film 2360B that does not overlap the plurality of photoresists PR may be removed.

Next, the lower auxiliary coating film 2340B may be removed by performing the wet etching process. The wet etching process may be performed using a buffered oxide etchant (“BOE”) or an etchant including diluted HF. In the process, a portion of the lower auxiliary coating film 2340B that does not overlap the plurality of photoresists PR may be removed.

As the lower auxiliary coating film 2340B and the lower main coating film 2360B are removed in the process, a temporary opening TOP may be defined, and a portion of the second surface ms2 of the mask substrate 2320 may be exposed at a portion that overlaps the temporary opening TOP.

It has been illustrated in FIG. 23 that a side surface md3 of the lower auxiliary coating film 2340B and a side surface me3 of the lower main coating film 2360B are inclined surfaces, but the disclosure is not limited thereto. The side surface md3 of the lower auxiliary coating film 2340B and the side surface me3 of the lower main coating film 2360B may also be formed as vertical surfaces toward one side of the third direction DR3 according to a process condition.

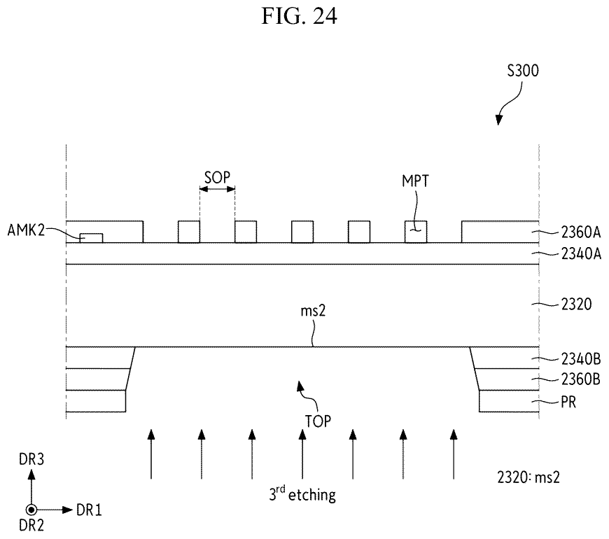

FIGS. 24 to 26 are cross-sectional views illustrating S300 of FIG. 18.

Third, the removing of the portion of the mask substrate by the wet etching process to form the mask opening (S300) is described.

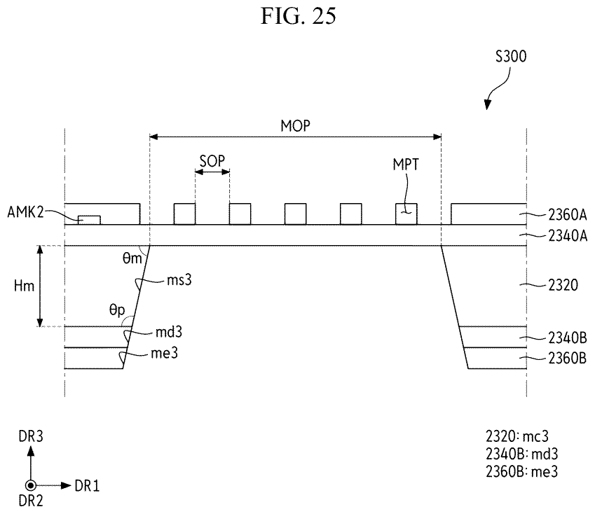

Referring to FIGS. 24 and 25, a photoresist PR is formed on the second surface ms2 of the mask substrate 2320, and a third etching process (3^{rd} etching) is performed. A plurality of photoresists PR may be disposed on the lower main coating film 2360B.

In the process, the third etching process (3^{rd} etching) may be performed toward the second surface ms2 of the mask substrate 2320. That is, the third etching process (3^{rd} etching) may be performed in the rear surface direction of the mask substrate 2320. The wet etching process may be performed using an etchant including tetramethyl ammonium hydroxide (“TMAH”) or potassium hydroxide (“KOH”).

In the process, the mask substrate 2320 that does not overlap the photoresist PR may be entirely removed, and accordingly, a mask opening MOP may be defined. In other words, the mask substrate 2320 that overlaps the temporary opening TOP may be entirely removed. In an embodiment, a thickness Hm of the mask substrate 2320 may have a range of 700 μm or more and 800 μm or less, for example.

As described above, in the deposition mask 2000 in an embodiment, the mask substrate 2320 may be removed by the wet etching process, and accordingly, a side surface ms3 of the mask substrate 2320 may be formed as an inclined surface. Specifically, a first inclination angle θm defined by the upper auxiliary coating film 2340A and the side surface ms3 of the mask substrate 2320 that face the mask opening MOP may be an acute angle, and a second inclination angle θp defined by the lower auxiliary coating film 2340B and the side surface ms3 of the mask substrate 2320 may be an obtuse angle. In an embodiment, the first inclination angle θm may have a range of 53° or more and 55° or less, and the second inclination angle θp may have a range of 125° or more and 127° or less.

In the process, a <110> crystal direction of a single crystal silicon substrate used as the mask substrate 2320 may be the first direction DR1, and accordingly, when the third etching process (3^{rd} etching) is performed, an undercut of the mask substrate 2320 may be minimized. In other words, in the process, the side surface me3 of the lower main coating film 2360B, the side surface md3 of the lower auxiliary coating film 2340B, and the side surface ms3 of the mask substrate 2320 may be disposed on the same line.

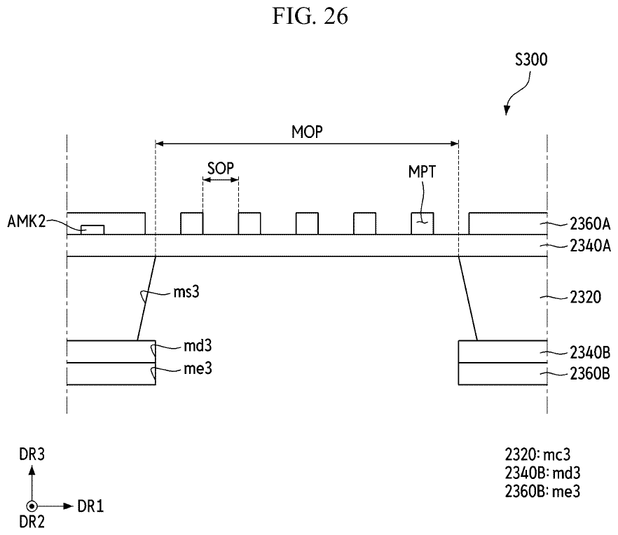

In an embodiment, in the process, when the side surface me3 of the lower main coating film 2360B and the side surface md3 of the lower auxiliary coating film 2340B are formed in a shape in which they protrude more than the side surface ms3 of the mask substrate 2320 toward the mask opening MOP as illustrated in FIG. 26, a structure illustrated in FIG. 25 may be formed by separately performing a photolithography process.

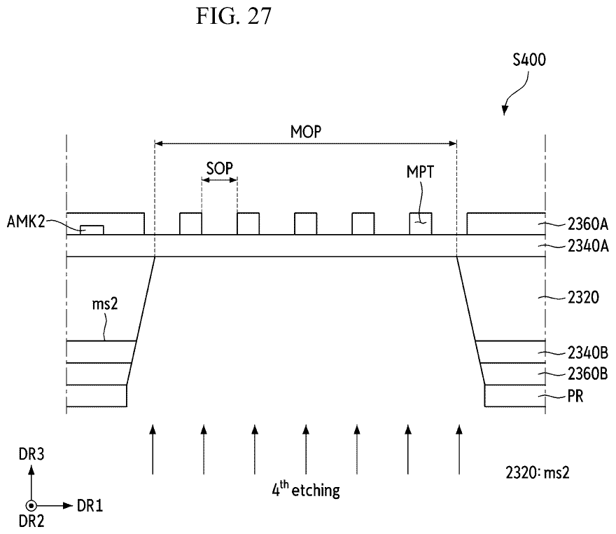

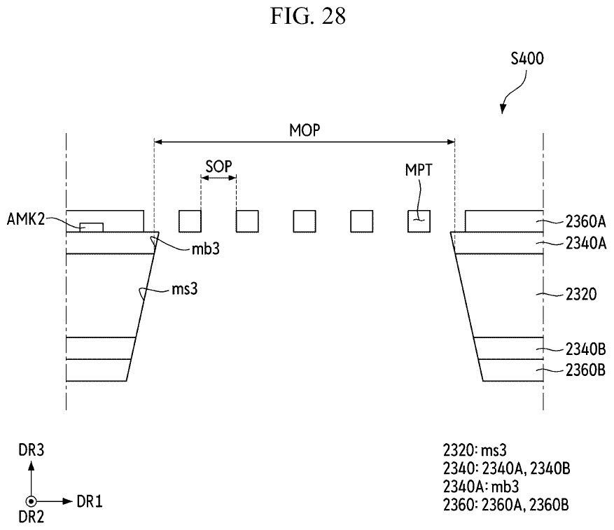

FIGS. 27 and 28 are cross-sectional views illustrating S400 of FIG. 18.

Fourth, the removing of the upper auxiliary coating film by the wet etching process to allow the pixel opening and the mask opening to be in communication with each other (S400) is described.

Referring to FIGS. 27 and 28, a photoresist PR is formed on the second surface ms2 of the mask substrate 2320, and a fourth etching process (4^{th} etching) is performed. A plurality of photoresists PR may be disposed on the lower main coating film 2360B.

In the process, the fourth etching process (4^{th} etching) may be performed toward the second surface ms2 of the mask substrate 2320. That is, the fourth etching process (4^{th} etching) may be performed in the rear surface direction of the mask substrate 2320. In the process, the upper auxiliary coating film 2340A that overlaps the mask opening MOP may be entirely removed, and for this reason, the mask opening MOP and the pixel opening SOP may be in communication with each other.

In an embodiment, a wet etching process may be performed as the fourth etching process (4^{th} etching). In an embodiment, the wet etching process may be performed using a BOE or an etchant including diluted HF.

In the process, a side surface mb3 of the upper auxiliary coating film 2340A may be disposed on the same line as the side surface ms3 of the mask substrate 2320, but is not limited thereto.

Consequently, the deposition mask 2000p illustrated in FIG. 15 may be manufactured.

The deposition mask 2000q illustrated in FIG. 16 may be formed by omitting the processes of forming and removing the auxiliary coating film 2340 among the above-described processes, and the deposition mask 2000r illustrated in FIG. 17 may be formed by adjusting a position of the photoresist PR in the forming of the auxiliary coating film and the main coating film on the mask substrate and the removing of the upper main coating film to define the pixel opening (S100) as described above.

By removing a portion of the mask substrate 2320 through the wet etching process in manufacturing processes of the deposition mask 2000 including the deposition masks 2000p, 2000r, and 2000q described above with reference to FIGS. 1 to 28, the side surface ms3 of the mask substrate 2320 may be formed as the inclined surface, and the first inclination angle θm (tapered angle) defined by the mask substrate 2320 and the upper auxiliary coating film 2340A may have the range of 53° or more and 55° or less.

The range of the first inclination angle θm (tapered angle) of the mask substrate 2320 described above is lower than the deposition incident angle θe of the deposition source 3200 disposed in the deposition device DD, such that deposition efficiency may be increased without including a separate margin area in at least one of the deposition mask 2000 or the mother semiconductor substrate 3000.

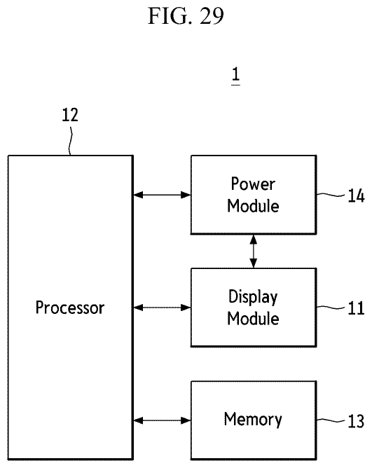

FIG. 29 is a block diagram of an electronic device according to one embodiment of the present disclosure.

Referring to FIG. 29, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

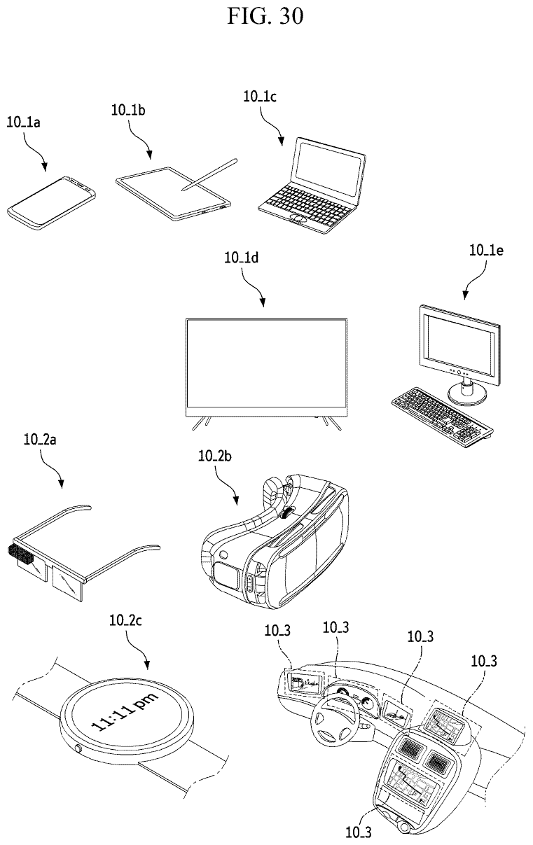

FIG. 30 is a schematic diagram of an electronic device according to various embodiments of the present disclosure.

Referring to FIG. 30, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

In addition, in the deposition mask 2000 in an embodiment, the <110> crystal direction of the single crystal silicon substrate used as the mask substrate 2320 is the first direction DR1, and accordingly, the undercut formed between the mask substrate 2320 and the lower auxiliary coating film 2340B when the third etching process (3^{rd} etching) is performed may be minimized. Accordingly, the deposition mask 2000 in an embodiment may have manufacturing easiness.

The disclosure should not be construed as being limited to the embodiments set forth herein. Rather, these embodiments are provided so that this disclosure will be thorough and complete and will fully convey the concept of the disclosure to those skilled in the art.

While the disclosure has been particularly shown and described with reference to embodiments thereof, it will be understood by those of ordinary skill in the art that various changes in form and details may be made therein without departing from the spirit or scope of the disclosure as defined by the following claims.

What is claimed is:

1. A deposition mask comprising:
a mask substrate surrounding a mask opening, the mask substrate including:
a first surface;
a second surface opposing the first surface;
a side surface facing the mask opening and extending to the first surface and the second surface, and
a first inclination angle defined by the first surface and the side surface of the mask substrate is 53° or more and 55° or less,
a main coating film disposed on the mask substrate; and
a mask pattern overlapping the mask opening and spaced apart from the main coating film with a pixel opening interposed therebetween,
wherein the first surface faces the main coating film.

2. The deposition mask of claim 1, wherein a second inclination angle defined by the second surface and the side surface of the mask substrate is an obtuse angle.

3. The deposition mask of claim 2, wherein the second inclination angle is 125° or more and 127° or less.

4. The deposition mask of claim 3, wherein the mask substrate includes silicon, and
the mask substrate has a circular shape in a plan view.

5. The deposition mask of claim 4, wherein a thickness of the mask substrate is 700 micrometers or more and 800 micrometers or less.

6. The deposition mask of claim 1, wherein a width of the mask opening in a direction parallel to the mask substrate becomes smaller toward the mask pattern in a direction perpendicular to the mask substrate.

7. The deposition mask of claim 1, wherein the main coating film includes:
an upper main coating film disposed on the first surface of the mask substrate; and
a lower main coating film disposed on the second surface of the mask substrate.

8. The deposition mask of claim 7, wherein a side surface of the lower main coating film facing the mask opening is disposed on a same line as the side surface of the mask substrate.

9. The deposition mask of claim 7, wherein a side surface of the upper main coating film facing the mask opening is depressed more than the side surface of the mask substrate in a direction opposite to a direction toward the mask opening.

10. The deposition mask of claim 8, wherein a side surface of the upper main coating film facing the mask opening protrudes more than the side surface of the mask substrate in a direction toward the mask opening.

11. The deposition mask of claim 1, wherein the mask pattern is disposed on a same line as the main coating film, and
the mask pattern and the main coating film include a same material as each other.

12. The deposition mask of claim 11, further comprising an auxiliary coating film disposed between the mask substrate and the main coating film,
wherein the auxiliary coating film and the main coating film include different inorganic materials.

13. The deposition mask of claim 12, wherein the main coating film and the auxiliary coating film surround the mask opening,
the mask pattern and the main coating film include silicon nitride, and
the auxiliary coating film includes silicon oxide.

14. The deposition mask of claim 12, wherein the pixel opening and the mask opening are in communication with each other.

15. A method of manufacturing a deposition mask, the method comprising:
forming an auxiliary coating film and a main coating film on a mask substrate and removing a portion of an upper main coating film to define a pixel opening;
removing portions of a lower main coating film and a lower auxiliary coating film;
removing a portion of the mask substrate to define a mask opening; and
removing a portion of an upper auxiliary coating film so that the pixel opening and the mask opening are in communication with each other,
wherein in the removing the portion of the mask substrate, the mask substrate is removed by a wet etching process.

16. The method of manufacturing a deposition mask of claim 15, wherein in the removing the portion of the mask substrate, the wet etching process is performed toward a rear surface direction of the mask substrate, and
a first inclination angle defined by the mask substrate and the upper auxiliary coating film is an acute angle.

17. The method of manufacturing a deposition mask of claim 16, wherein the first inclination angle is 53° or more and 55° or less.

18. The method of manufacturing a deposition mask of claim 17, wherein a thickness of the mask substrate is 700 micrometers or more and 800 micrometers or less, and
in the removing the portion of the mask substrate, the mask substrate overlapping the mask opening is completely removed.

19. The method of manufacturing a deposition mask of claim 15, wherein in the removing the portion of the upper auxiliary coating film, the upper auxiliary coating film is removed through the wet etching process performed in a rear surface direction of the mask substrate.

20. An electronic device comprising:
a display device formed using a deposition mask;
the deposition mask comprising:
a mask substrate surrounding a mask opening, the mask substrate including:
a first surface;
a second surface opposing the first surface;
a side surface facing the mask opening and extending to the first surface and the second surface, and
a first inclination angle defined by the first surface and the side surface of the mask substrate is 53° or more and 55° or less;
a main coating film disposed on the mask substrate; and
a mask pattern overlapping the mask opening and spaced apart from the main coating film with a pixel opening interposed therebetween,
wherein the first surface faces the main coating film.
